(19) United States
(12) Patent Application Publication
(10) Pub. No.: US 2026/0206213 A1
(43) Pub. Date: Jul. 16, 2026

(54) SEMICONDUCTOR STRUCTURE AND MANUFACTURING METHOD THEREOF

(71) Applicant: Winbond Electronics Corp., Taichung City (TW)

(72) Inventors: Cheng-Chih Hsu, Tainan City (TW); Chun-Chieh Wang, Taichung (TW)

(73) Assignee: Winbond Electronics Corp., Taichung City (TW)

(21) Appl. No.: 19/237,004

(22) Filed: Jun. 13, 2025

(30) Foreign Application Priority Data
Jan. 13, 2025 (TW) 114101311

(51) Int. Cl. H10B 12/00

(52) U.S. Cl. CPC H10B 12/485; H10B 12/02; H10B 12/482; H10B 12/488

(57) ABSTRACT

A semiconductor structure and a manufacturing method thereof. The semiconductor structure includes a semiconductor device, a plurality of contact structures and a plurality of first signal lines. The contact structures are located in the semiconductor device. A shape of a vertical projection of at least one of the contact structures on the semiconductor device includes a concave side. The first signal lines are located on the contact structures, and at least one of the first signal lines overlaps the concave side.

### CROSS-REFERENCE TO RELATED APPLICATION

This application claims the priority benefit of Taiwan application serial no. 114101311, filed on January 13, 2025. The entirety of the above-mentioned patent application is hereby incorporated by reference herein and made a part of this specification.

### BACKGROUND

### Technical Field

The present invention relates to a semiconductor structure and a method of manufacturing the same.

### Related Art

With the rapid advancement of technology, in order to achieve the trend of electronic devices becoming lighter, thinner, shorter, and smaller, the dimensions of semiconductor structures within electronic devices must also be continuously reduced. Generally, when fabricating these miniature and precise semiconductor structures, photolithography processes are used to accurately define the patterns and structures of components. Currently, semiconductor manufacturers are actively investing in developing technologies to further shrink the feature dimensions of components, thereby improving device performance and integration level.

### SUMMARY

The present invention provides a semiconductor structure and a method of manufacturing the same, which may shrink the feature dimensions of the contact structure.

At least one embodiment of the present invention provides a method of manufacturing a semiconductor structure, including the following steps. Forming a first mask structure above a semiconductor device. Forming a second mask structure above the first mask structure. Forming a first opening pattern in the second mask structure. Forming a third mask structure on the second mask structure and in the first opening pattern. Using the third mask structure as a mask to remove at least a part of the second mask structure surrounded by the third mask structure, to form a second opening pattern in the third mask structure. Etching the first mask structure located under the third mask structure through the second opening pattern, to form a third opening pattern in the first mask structure. Etching the semiconductor device through the third opening pattern, to form a fourth opening pattern in the semiconductor device. Forming a filling material layer in the fourth opening pattern. Forming a plurality of signal lines on the filling material layer. Using the plurality of signal lines as a mask to etch the filling material layer, to form a plurality of contact structures.

At least one embodiment of the present invention provides a semiconductor structure, which includes a semiconductor device, a plurality of contact structures, and a plurality of first signal lines. The contact structures are located in the semiconductor device. The vertical projection of at least one of the plurality of contact structures on the semiconductor device includes a shape with concave sides. The plurality of first signal lines are located on the plurality of contact structures, and at least one of the plurality of first signal lines overlaps with the concave sides.

### BRIEF DESCRIPTION OF THE DRAWINGS

FIG. 1 is a top view schematic diagram of a semiconductor structure according to an embodiment of the present invention.

FIG. 2A to FIG. 2L and FIG. 3A to FIG. 3N are cross-sectional schematic diagrams of various stages of a method of manufacturing a semiconductor structure according to an embodiment of the present invention.

FIG. 4A to FIG. 4H are top view schematic diagrams of various stages of a method of manufacturing a semiconductor structure according to an embodiment of the present invention.

FIG. 5 is a cross-sectional schematic diagram of a semiconductor structure according to an embodiment of the present invention.

### DESCRIPTION OF THE EMBODIMENTS

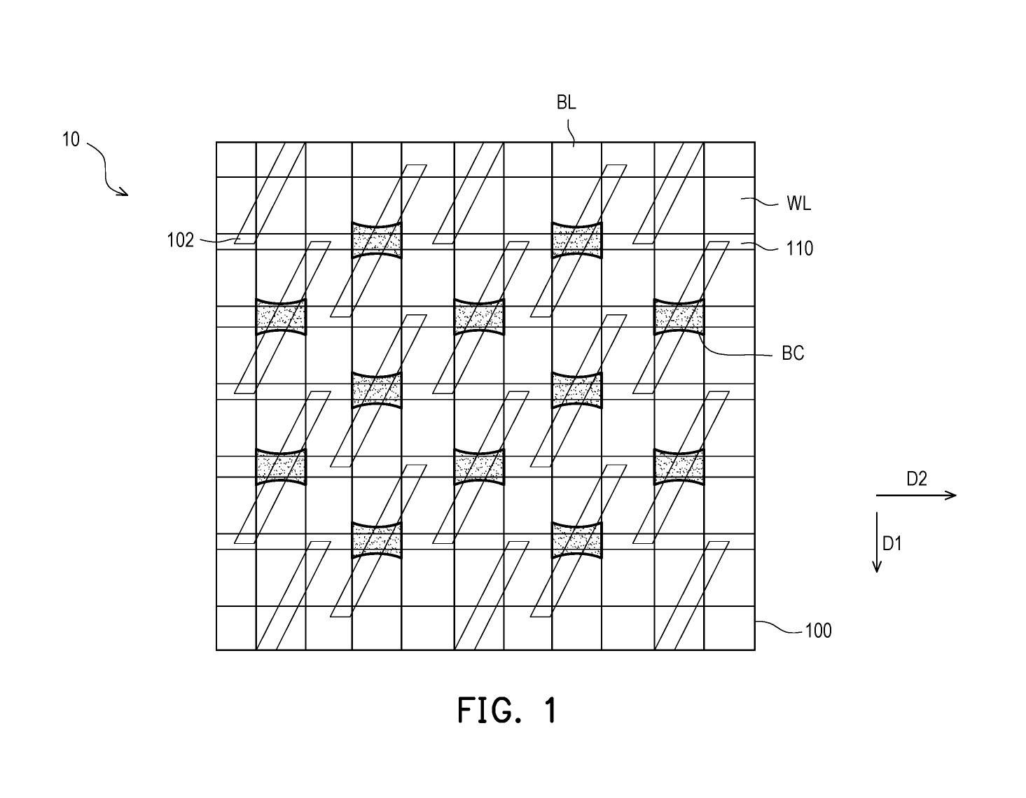

Referring to FIG. 1, the semiconductor structure 10 includes a substrate 100, isolation structures 110, active regions 102, bit lines BL (or first signal lines), word lines WL (or second signal lines), and contact structures BC. The bit lines BL may be multiple in number and are disposed on the substrate 100. Each bit line BL extends along a first direction D1, and adjacent bit lines BL are arranged at fixed intervals in a second direction D2. The word lines WL may also be multiple in number and are disposed in the substrate 100. Each word line WL extends along the second direction D2, and adjacent word lines WL are arranged at fixed intervals in the first direction D1. The word lines WL may be buried structures, meaning that the top surfaces of the word lines WL may be lower than the top surface of the substrate 100. For example, the word lines WL may be embedded within the substrate 100 to achieve a more compact structural design.

In some embodiments, the isolation structures 110 may be formed in the substrate 100 to define the area of the active regions 102 and to separate adjacent active regions 102 from each other. Multiple active regions 102 may be formed in the substrate 100, with each active region 102 extending generally along a direction that forms an angle with the first direction D1. This design helps to improve the integration level and performance of the components.

As shown in FIG. 1, each active region 102 spans across two word lines WL and cross one bit line BL. There is an overlapping region between each active region 102 and its corresponding bit line BL, with non-overlapping regions formed on both sides of the overlapping region. Storage node contacts (not shown) are disposed in these non-overlapping regions for electrical connection to capacitors (not shown). Each storage node contact is located between two adjacent bit lines BL and between two adjacent word lines WL.

In some embodiments, a contact structure BC is disposed at the overlapping region between each active region 102 and its corresponding bit line BL. When each bit line BL crosses its corresponding word lines WL, it may be electrically connected to a doped region of the substrate 100 located between two word lines WL through the contact structure BC. This design helps to achieve more efficient signal transmission.

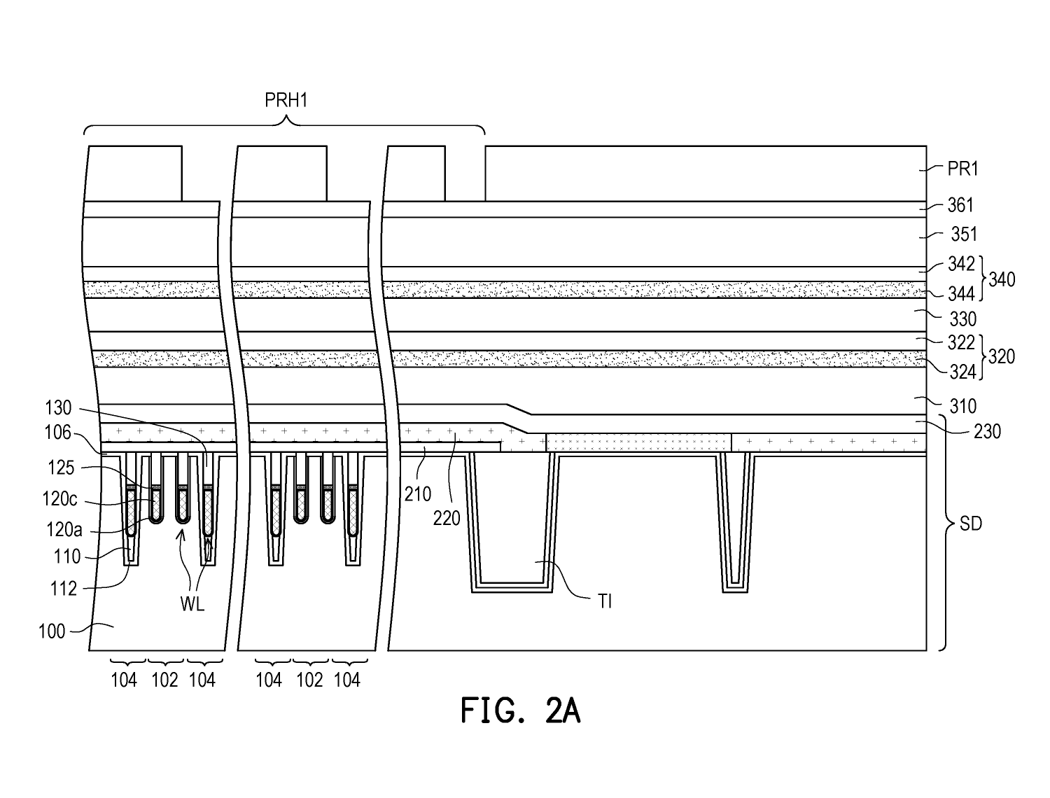

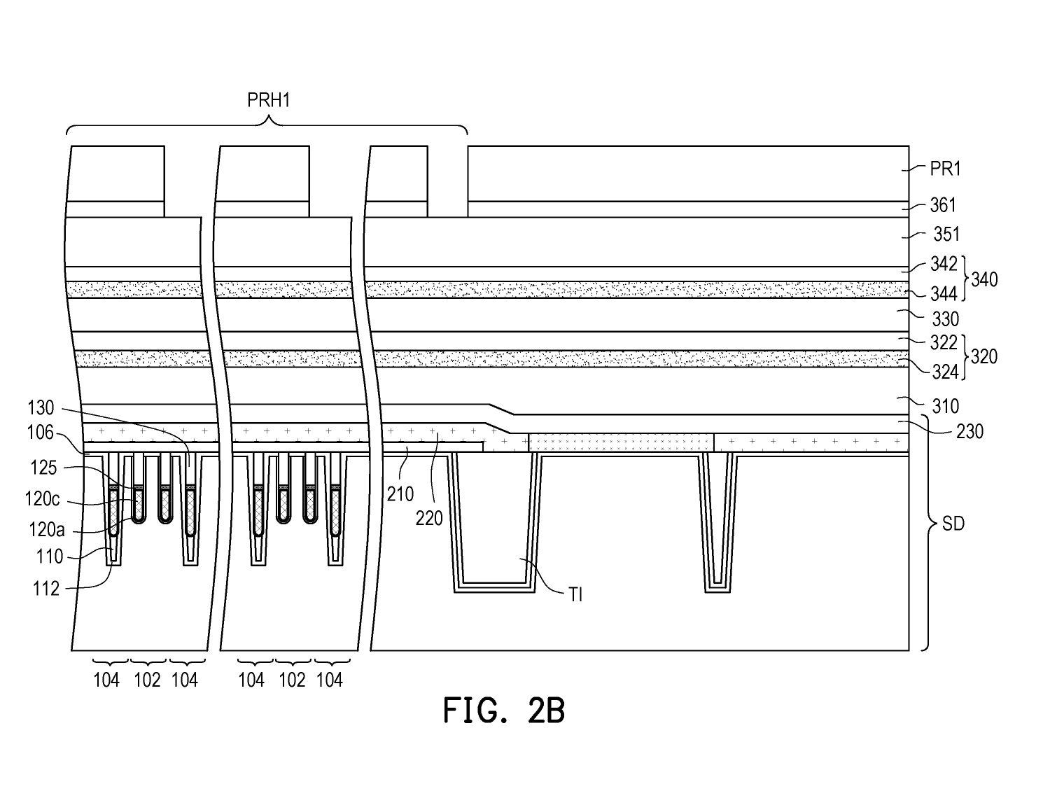

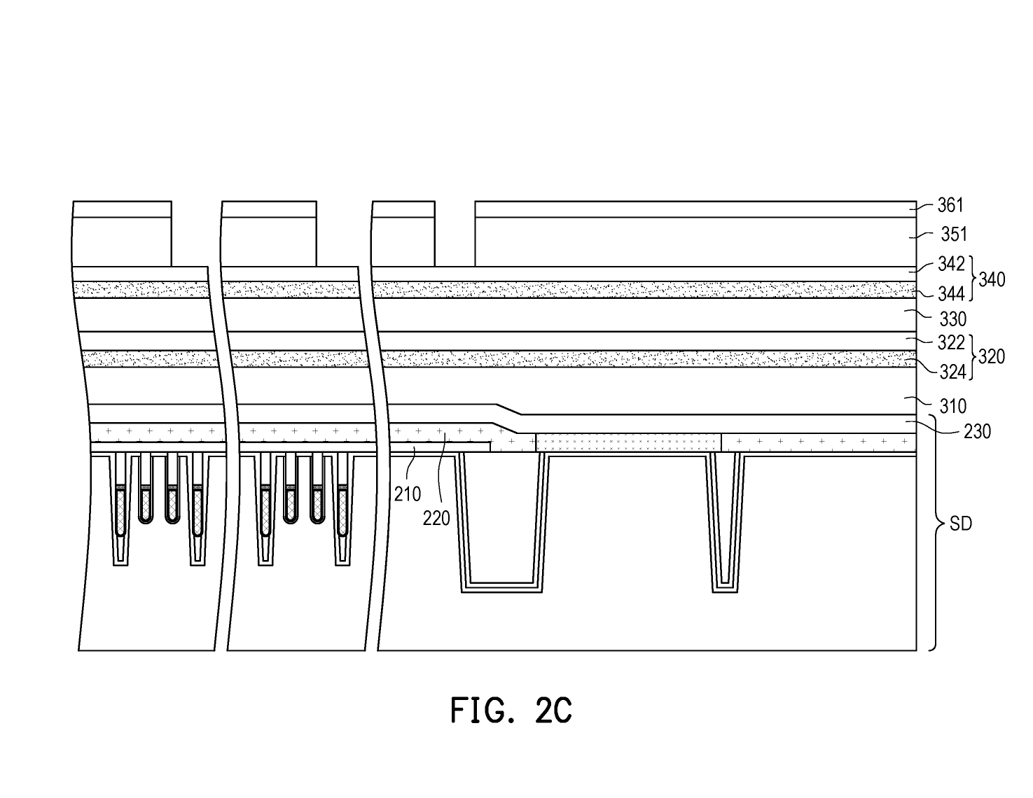

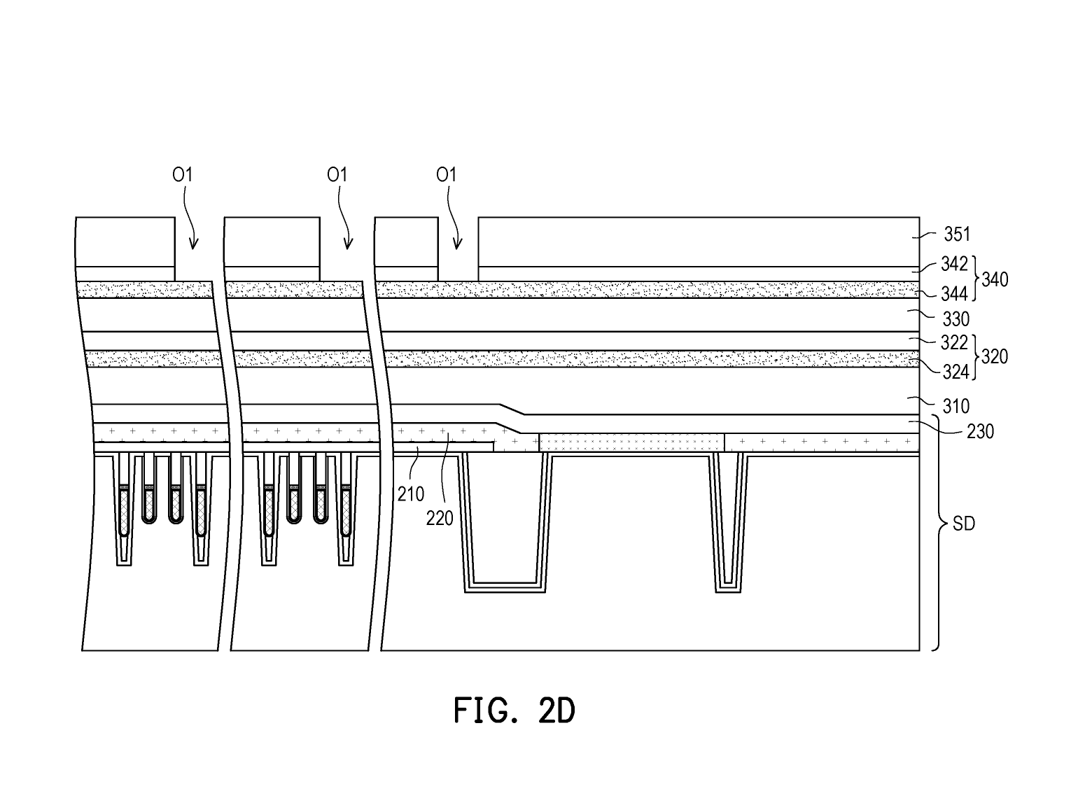

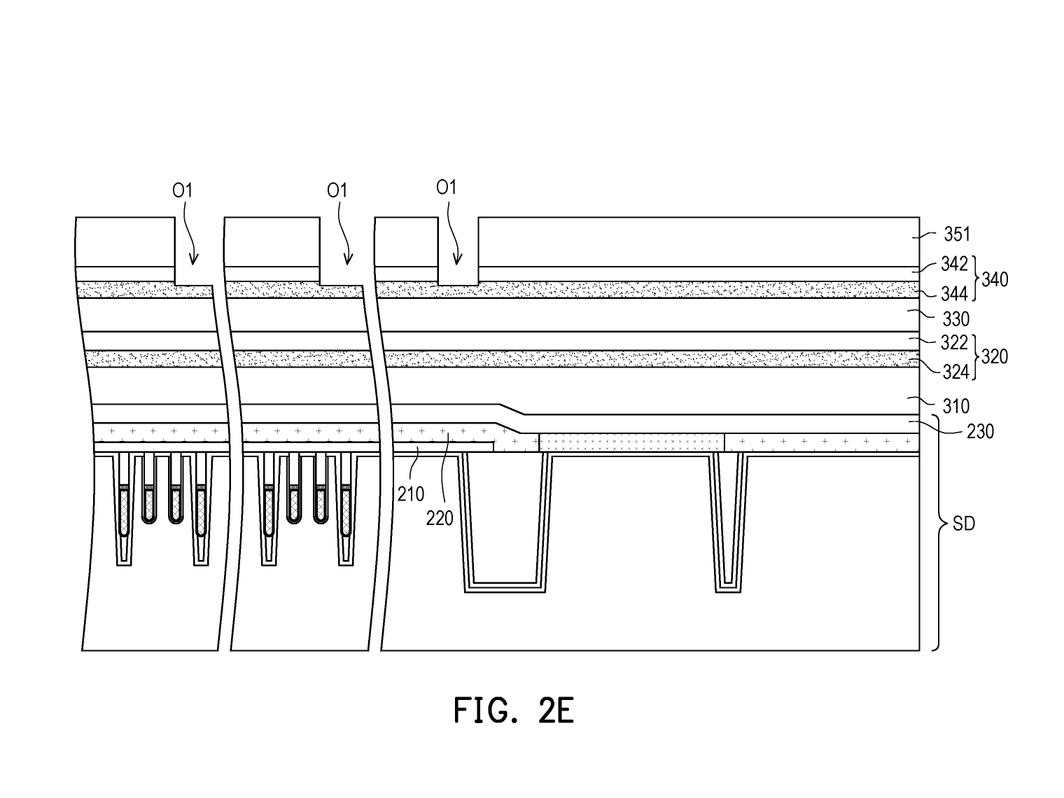

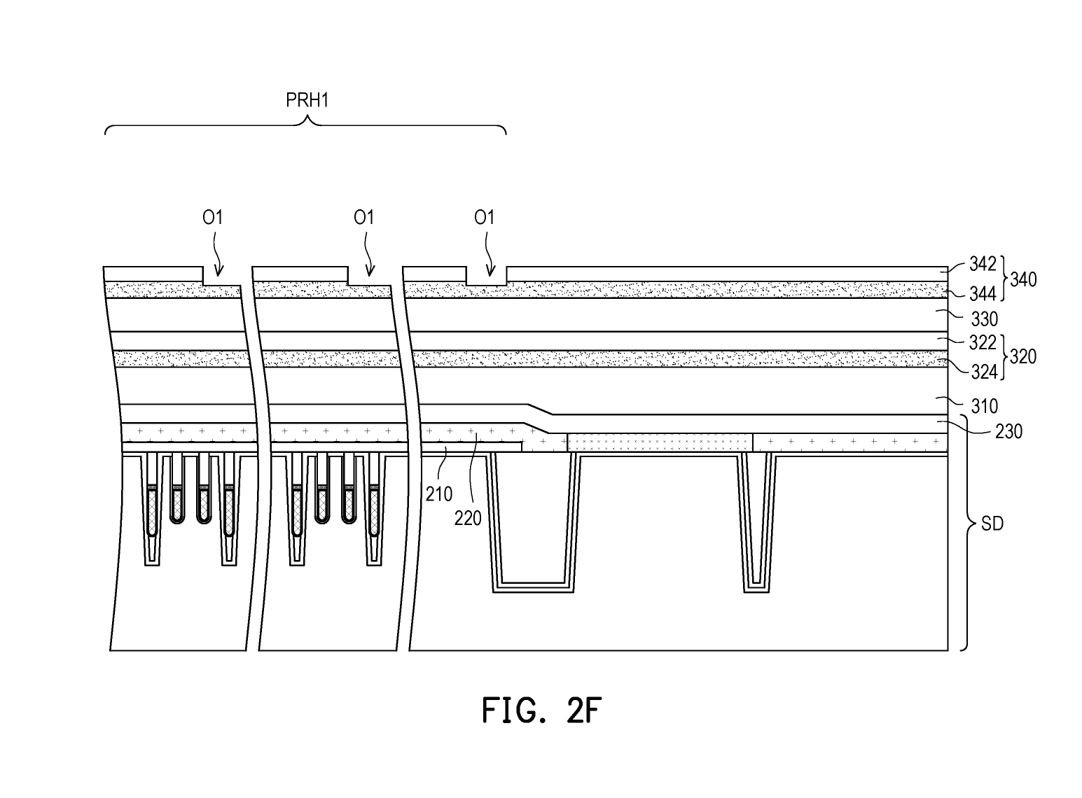

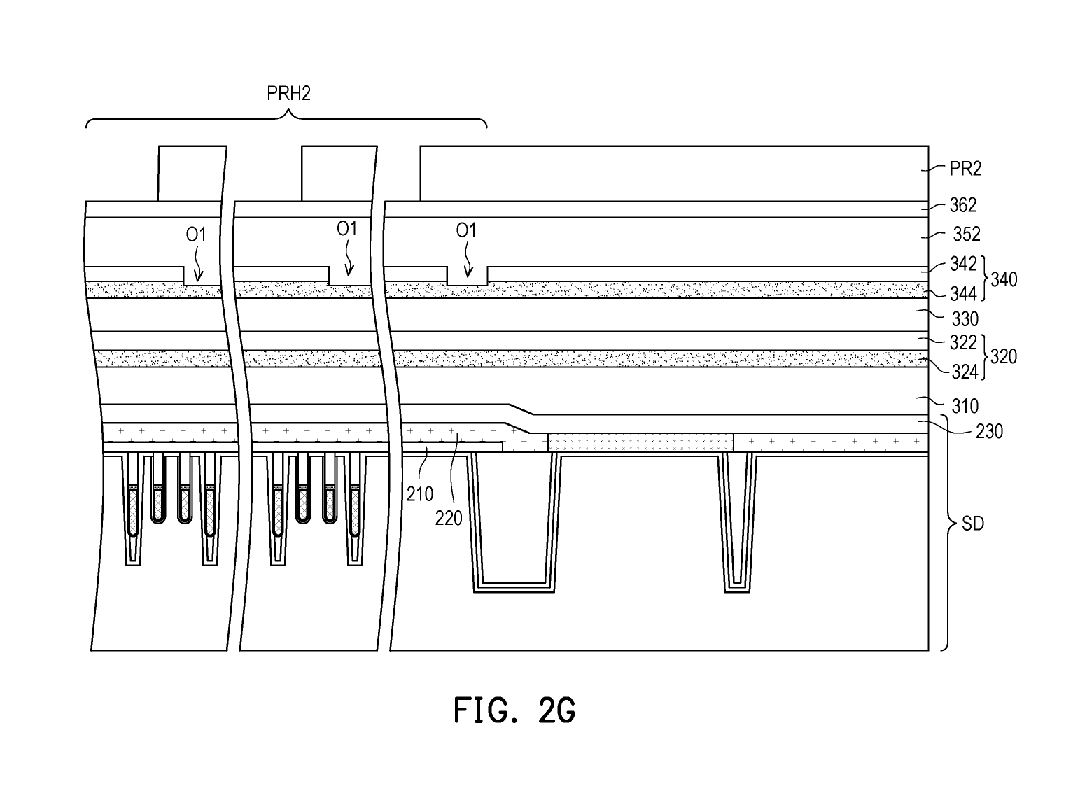

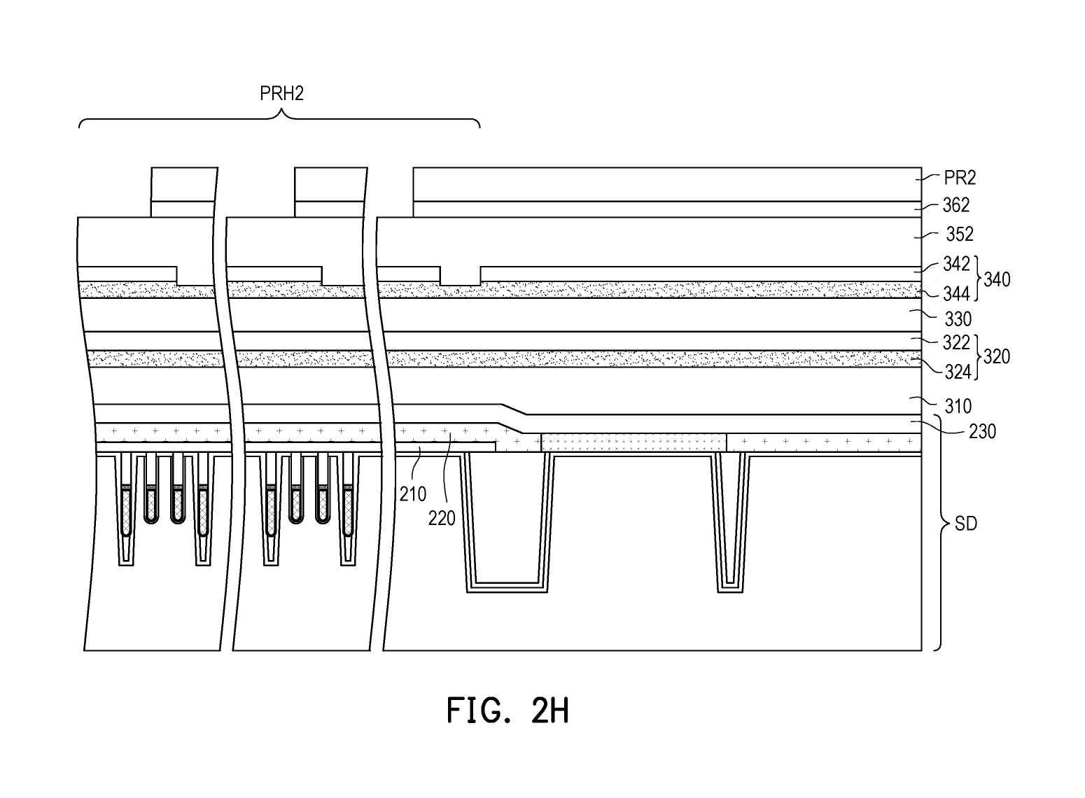

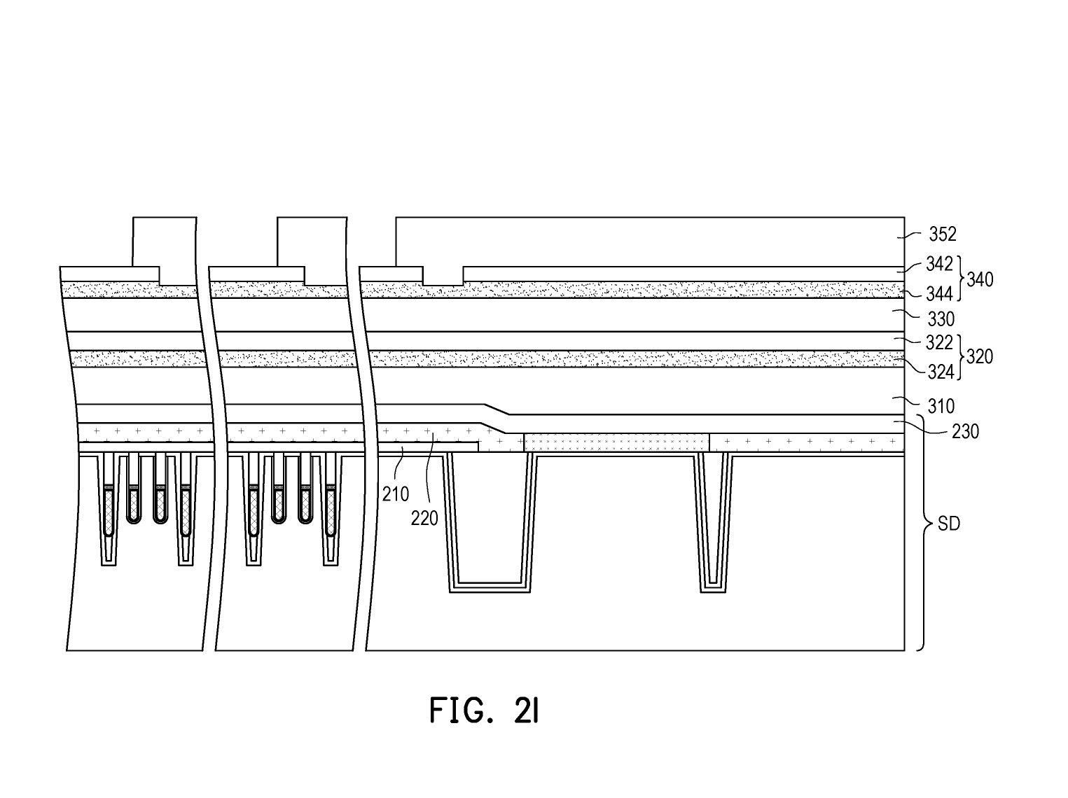

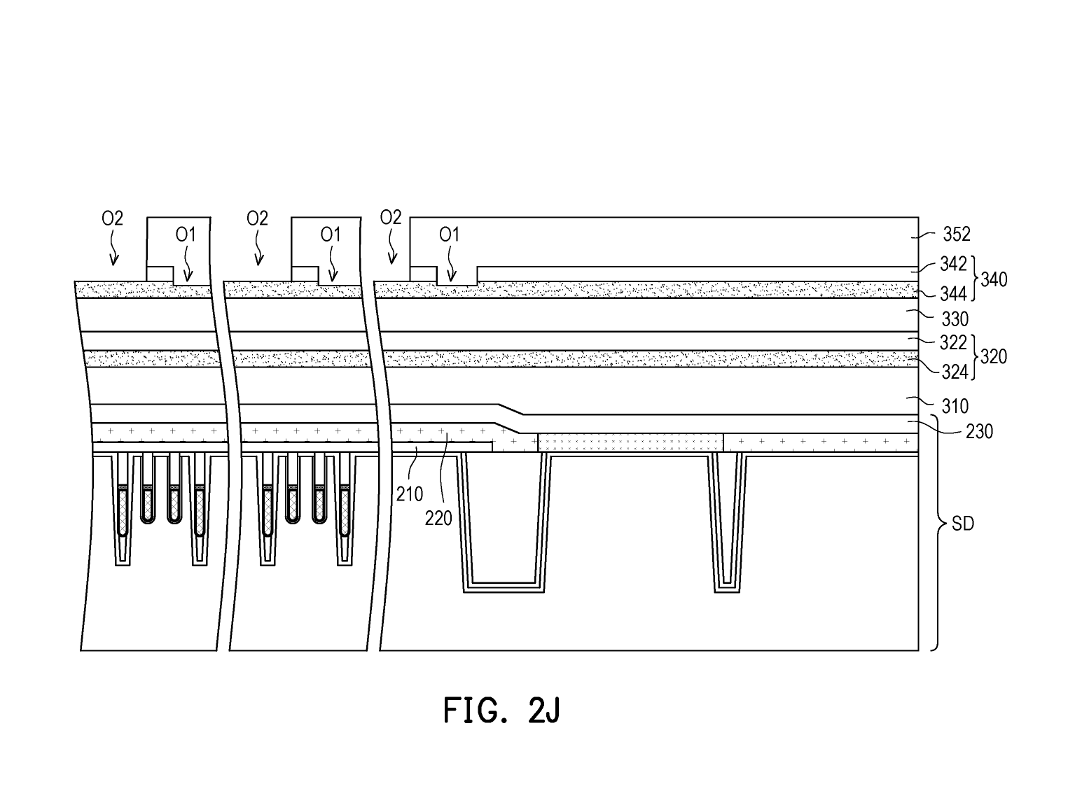

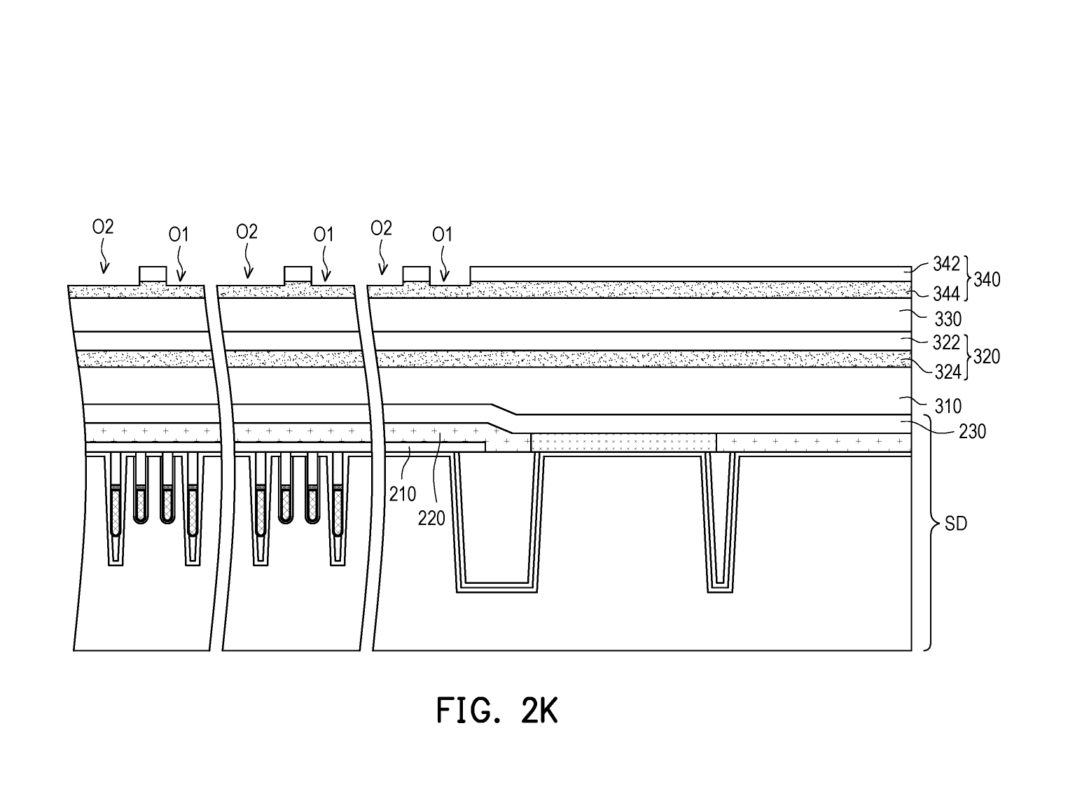

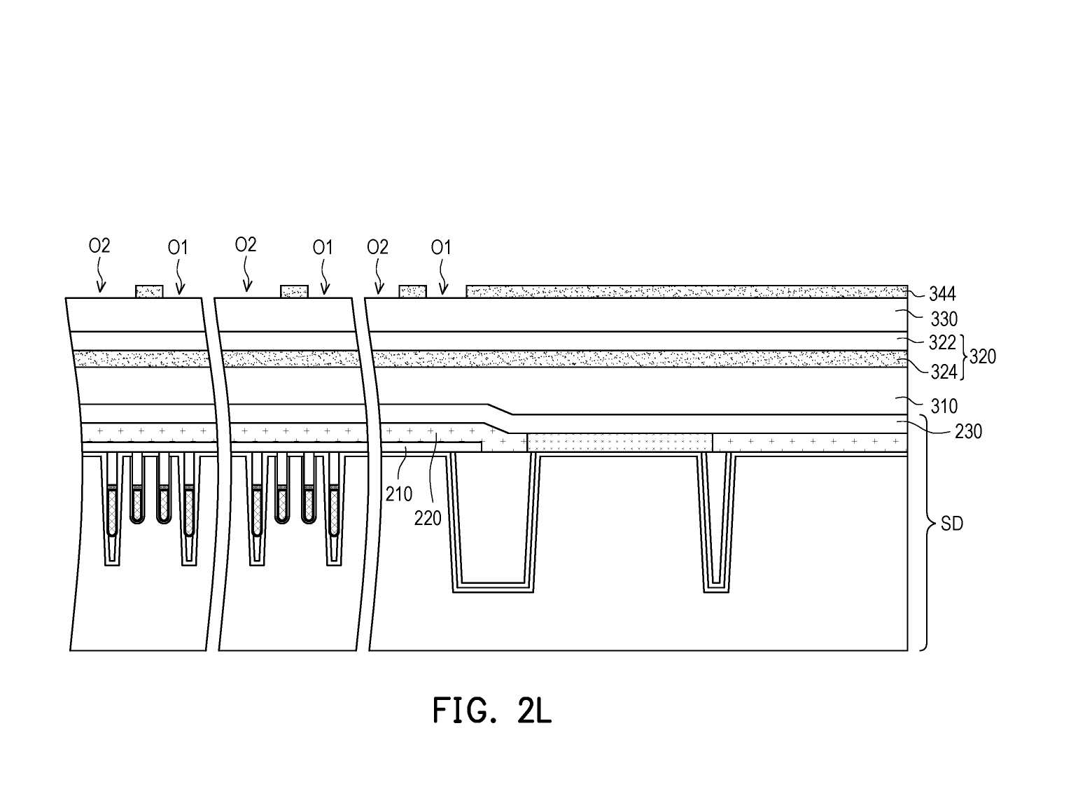

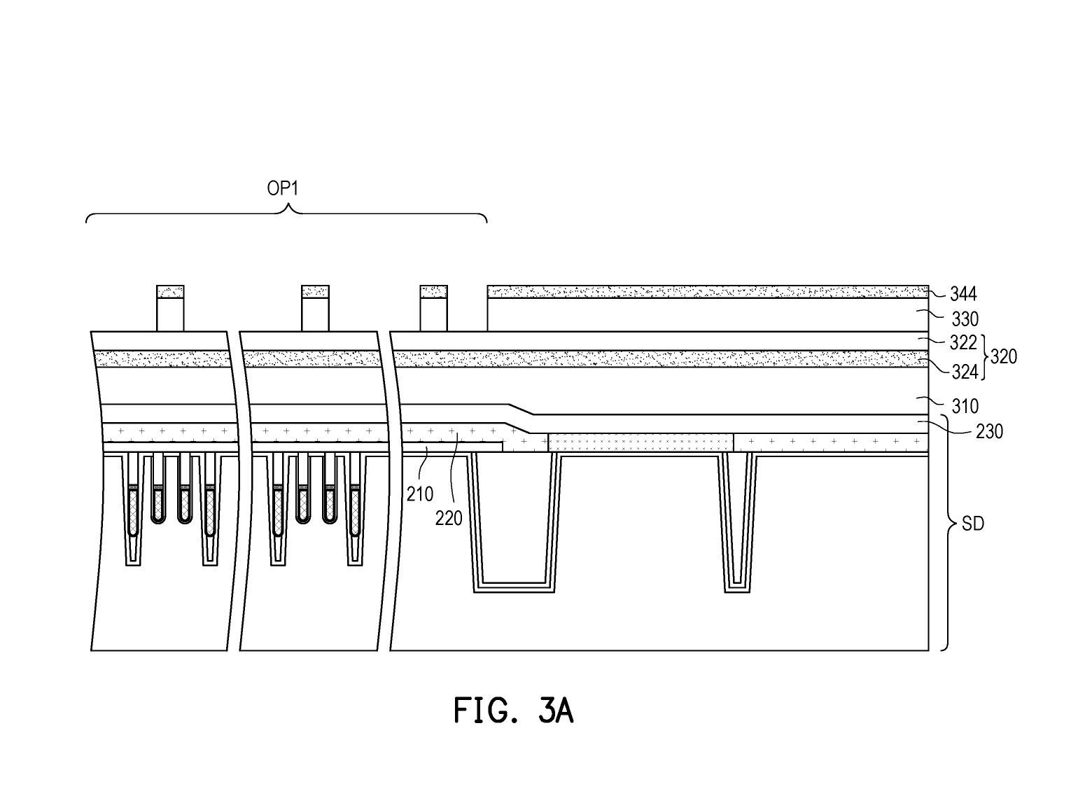

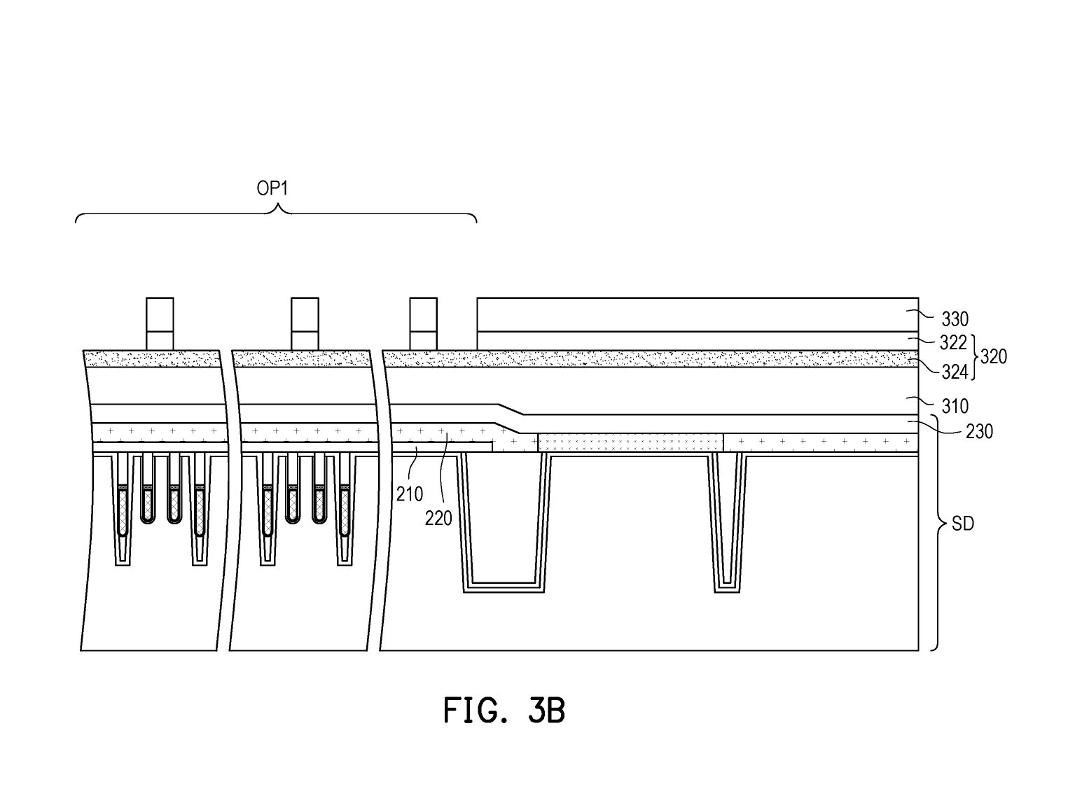

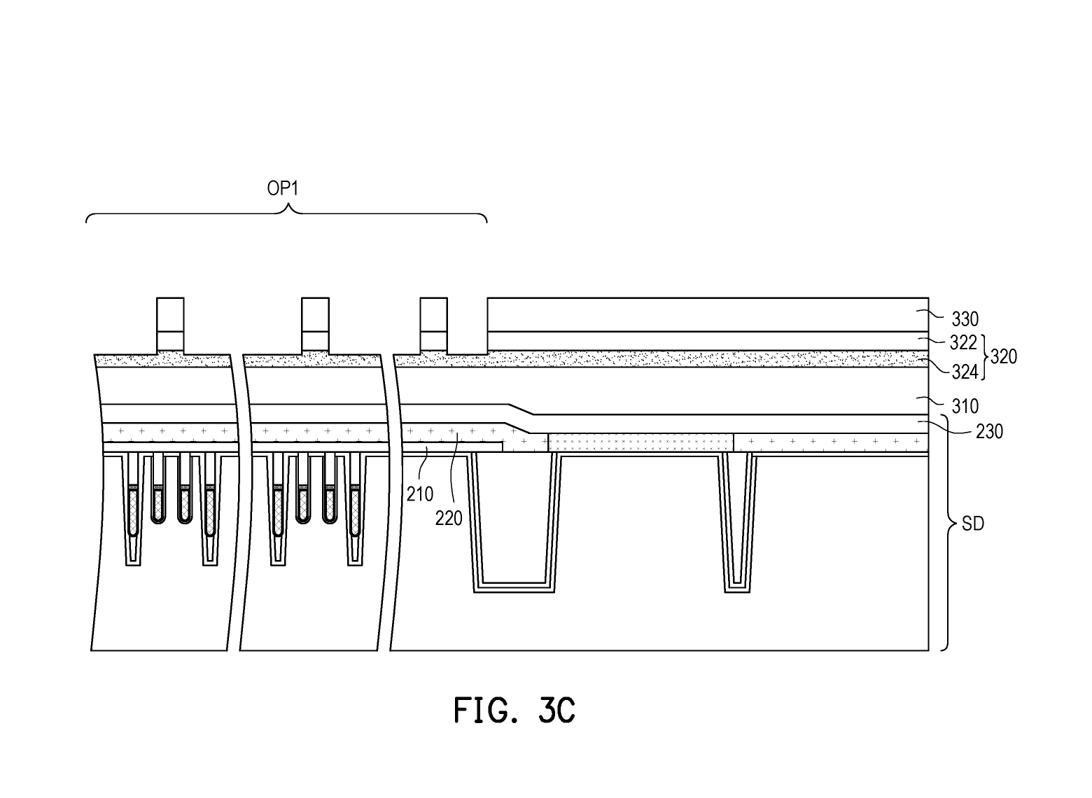

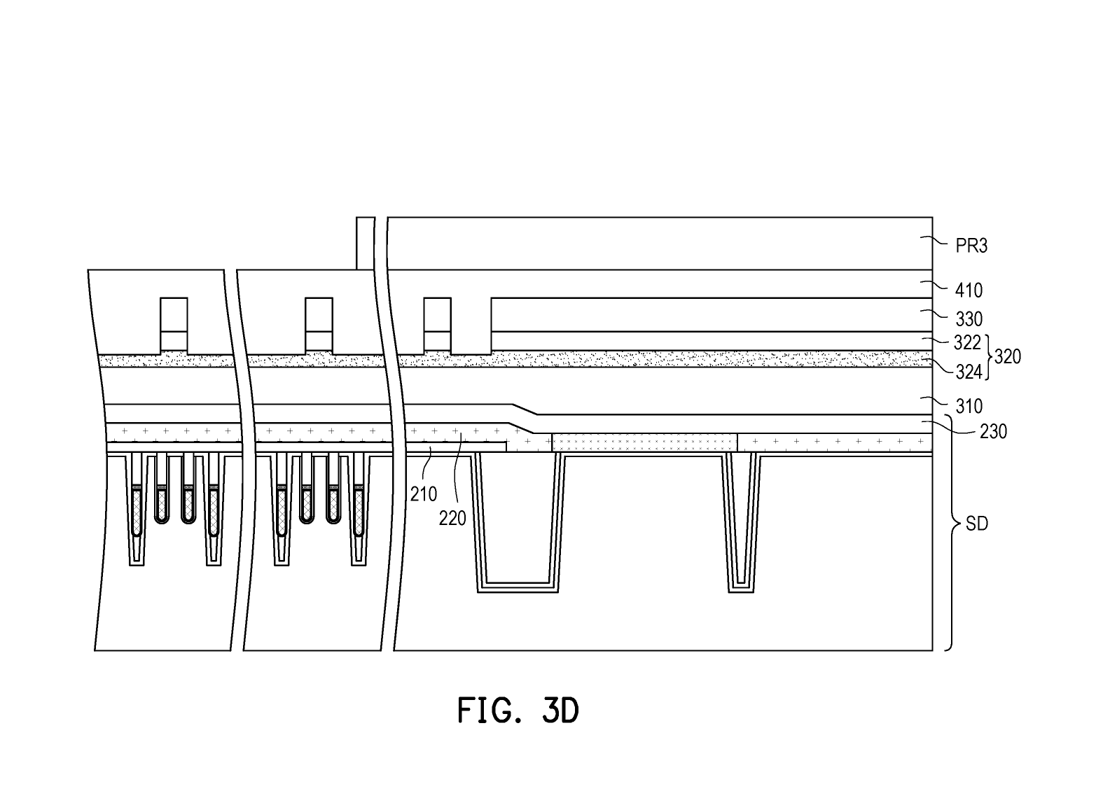

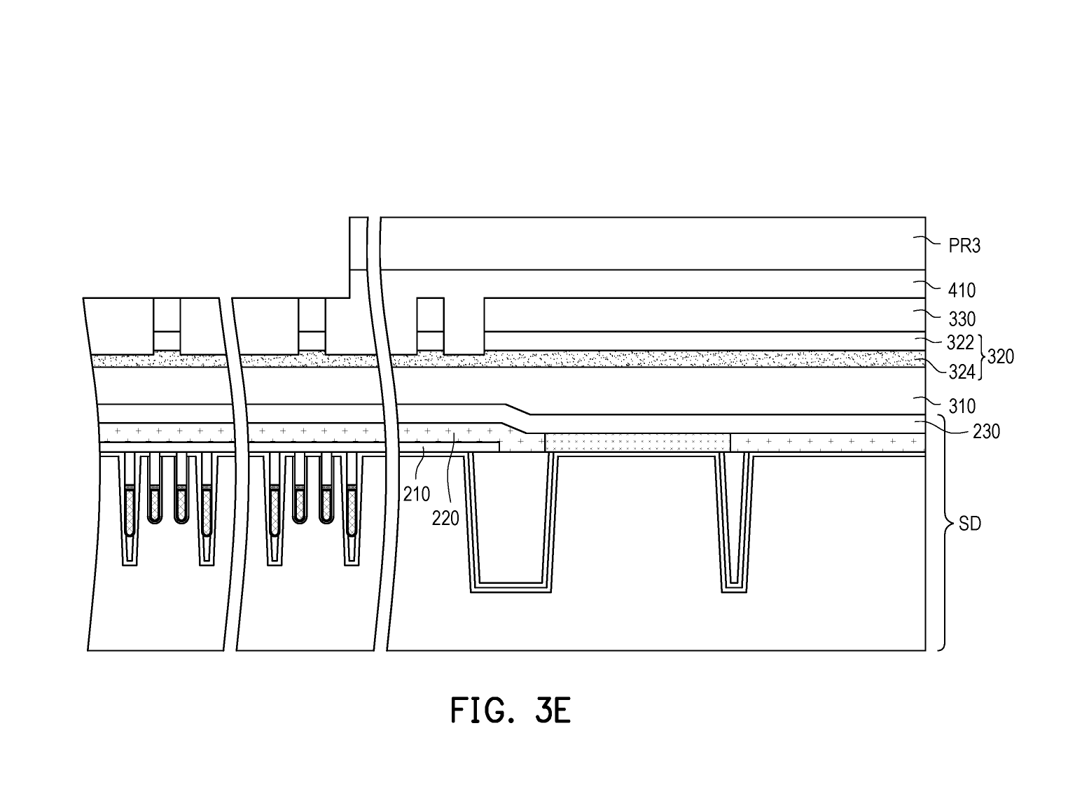

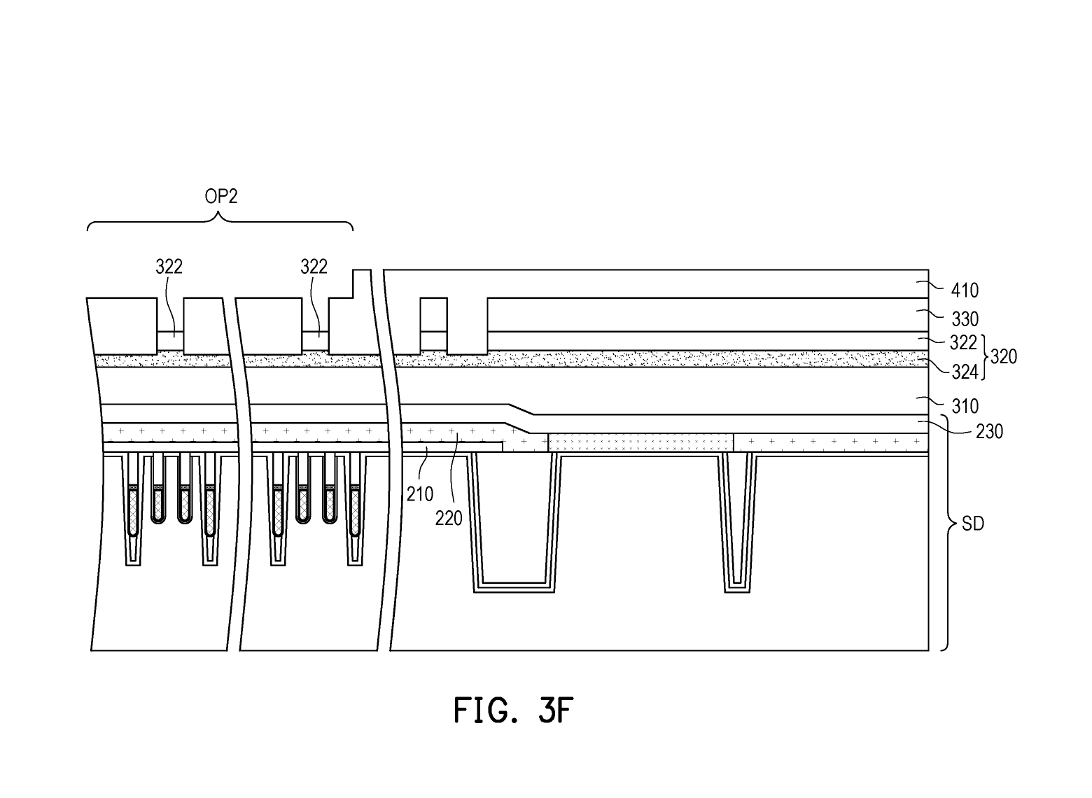

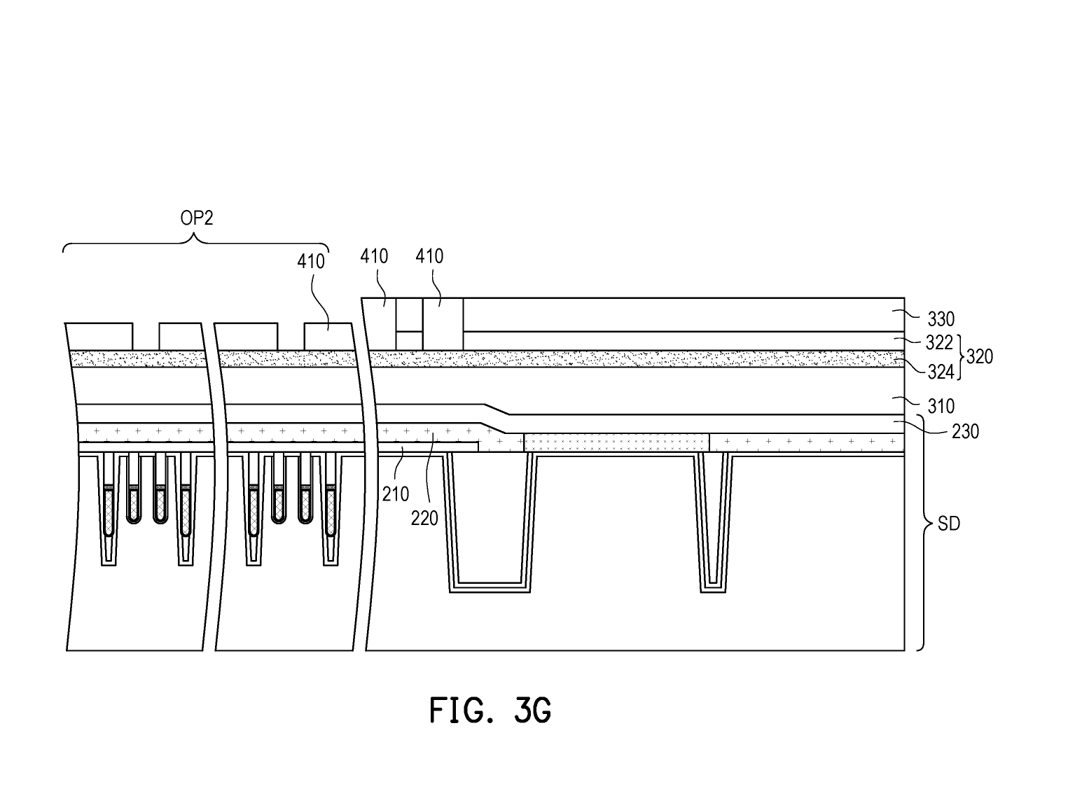

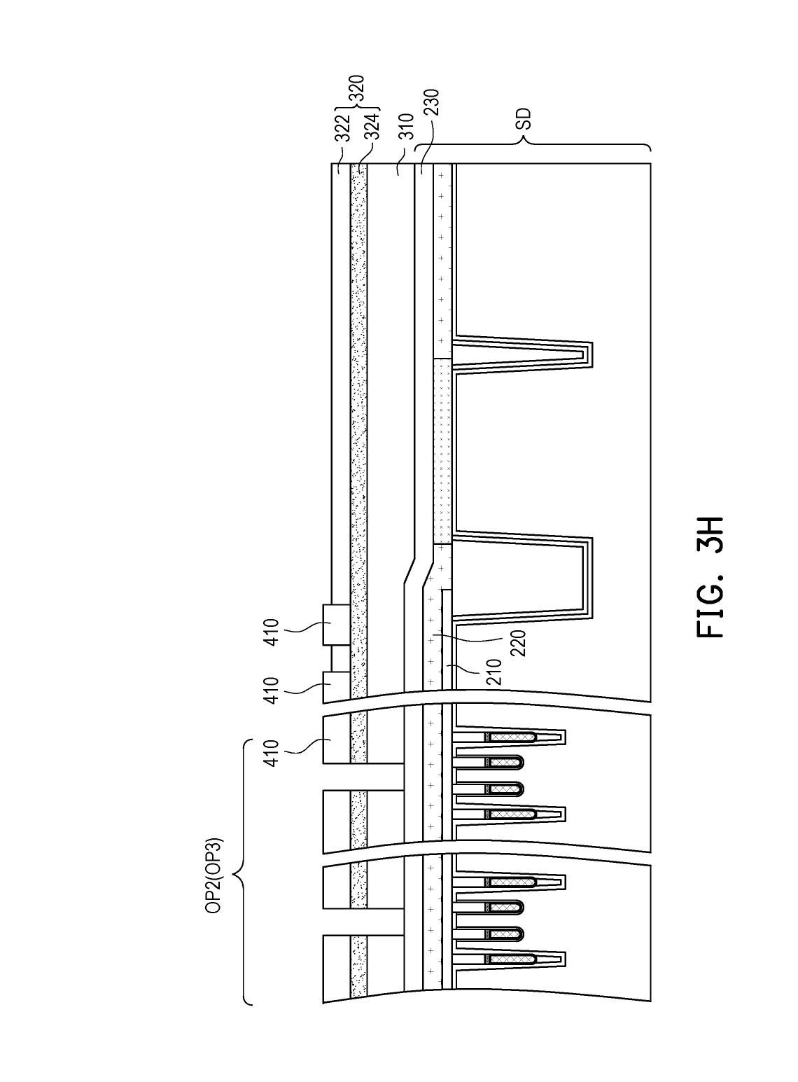

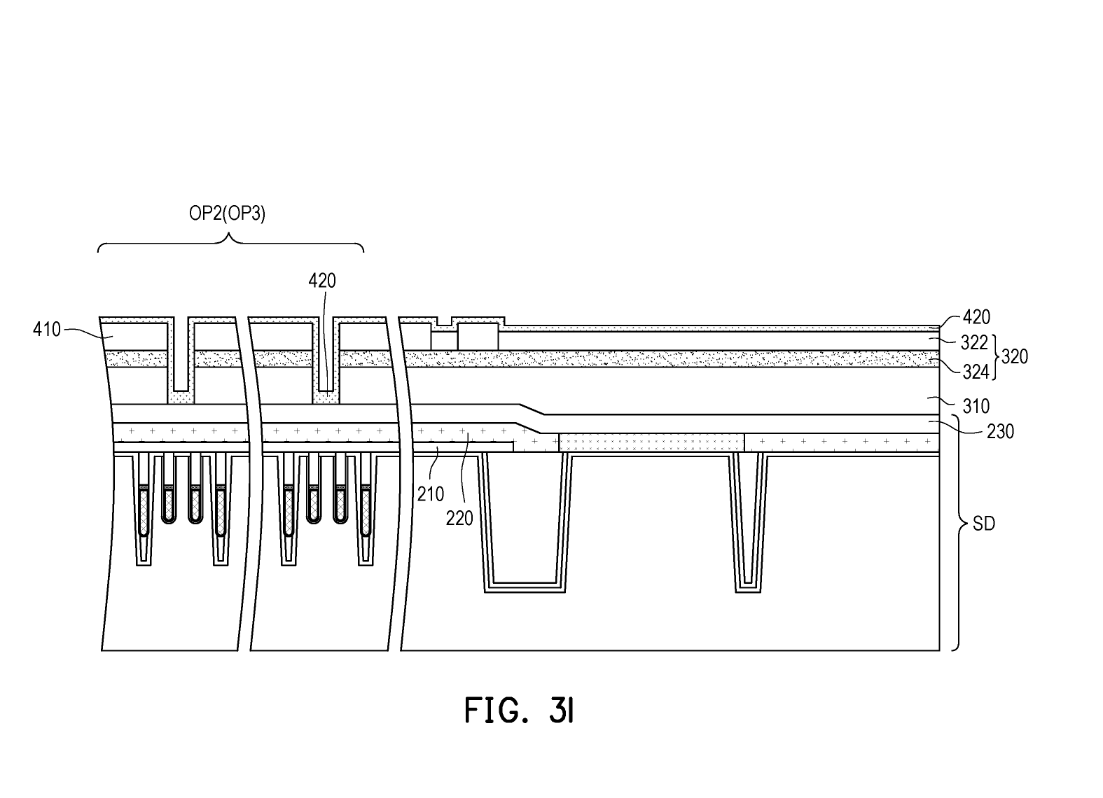

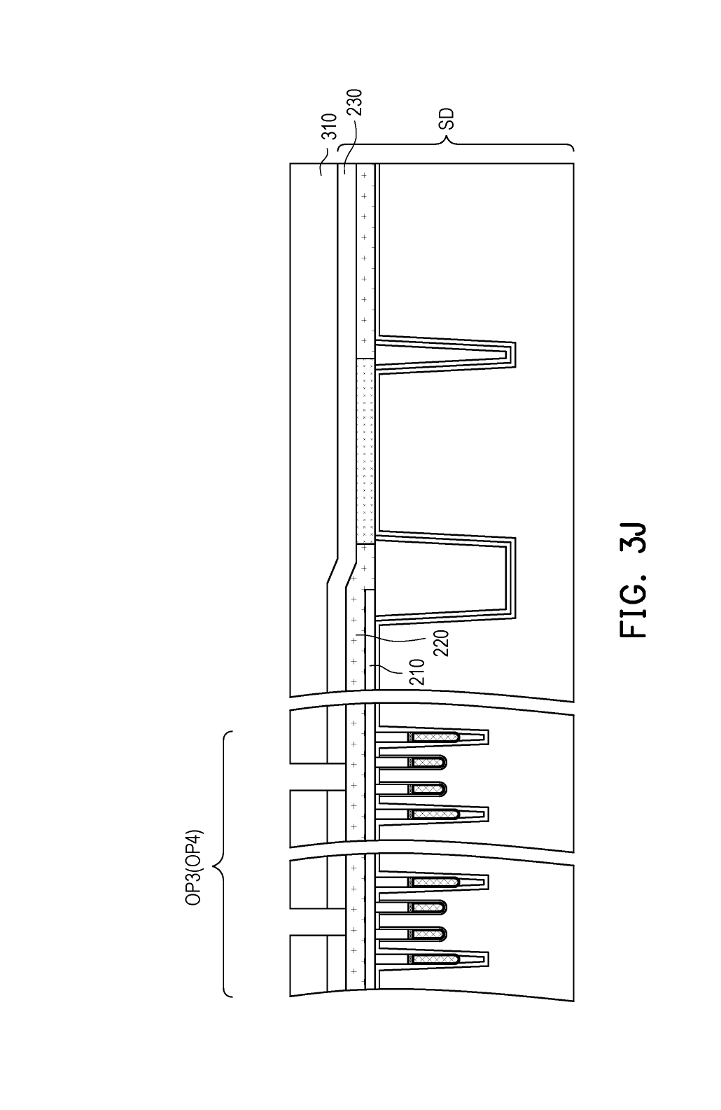

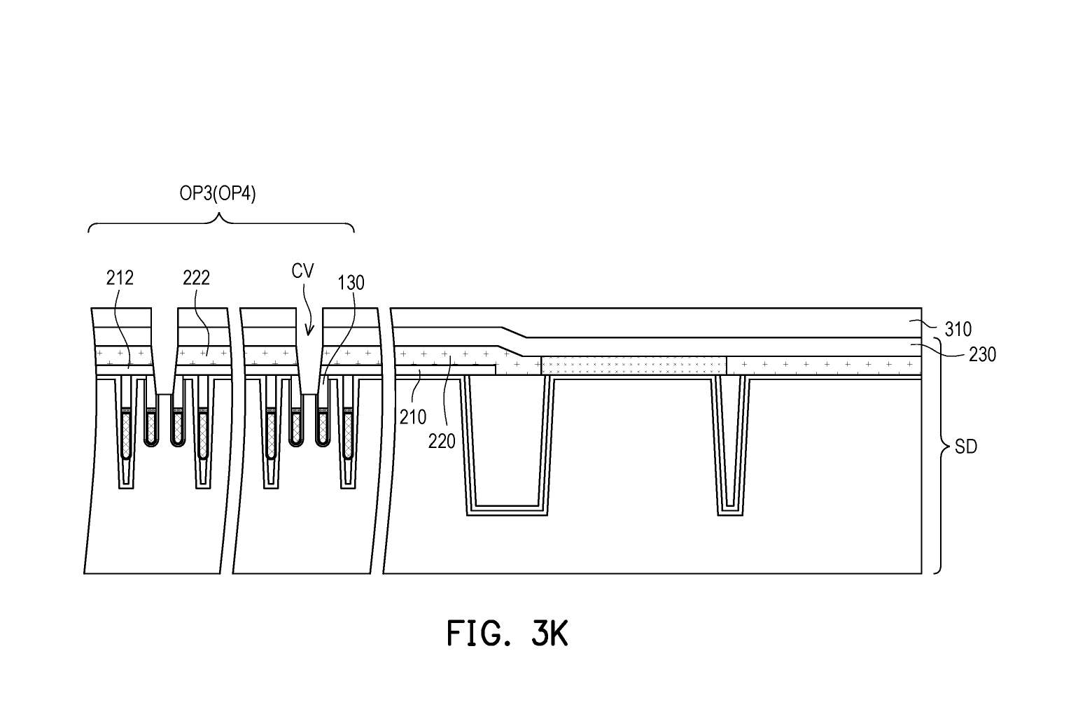

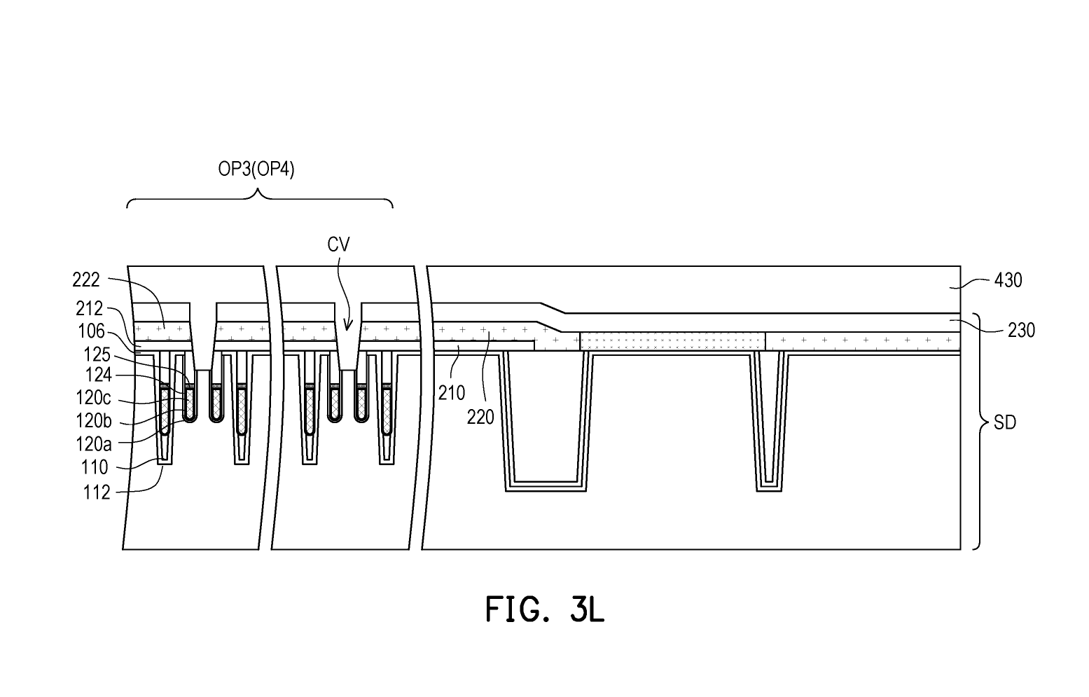

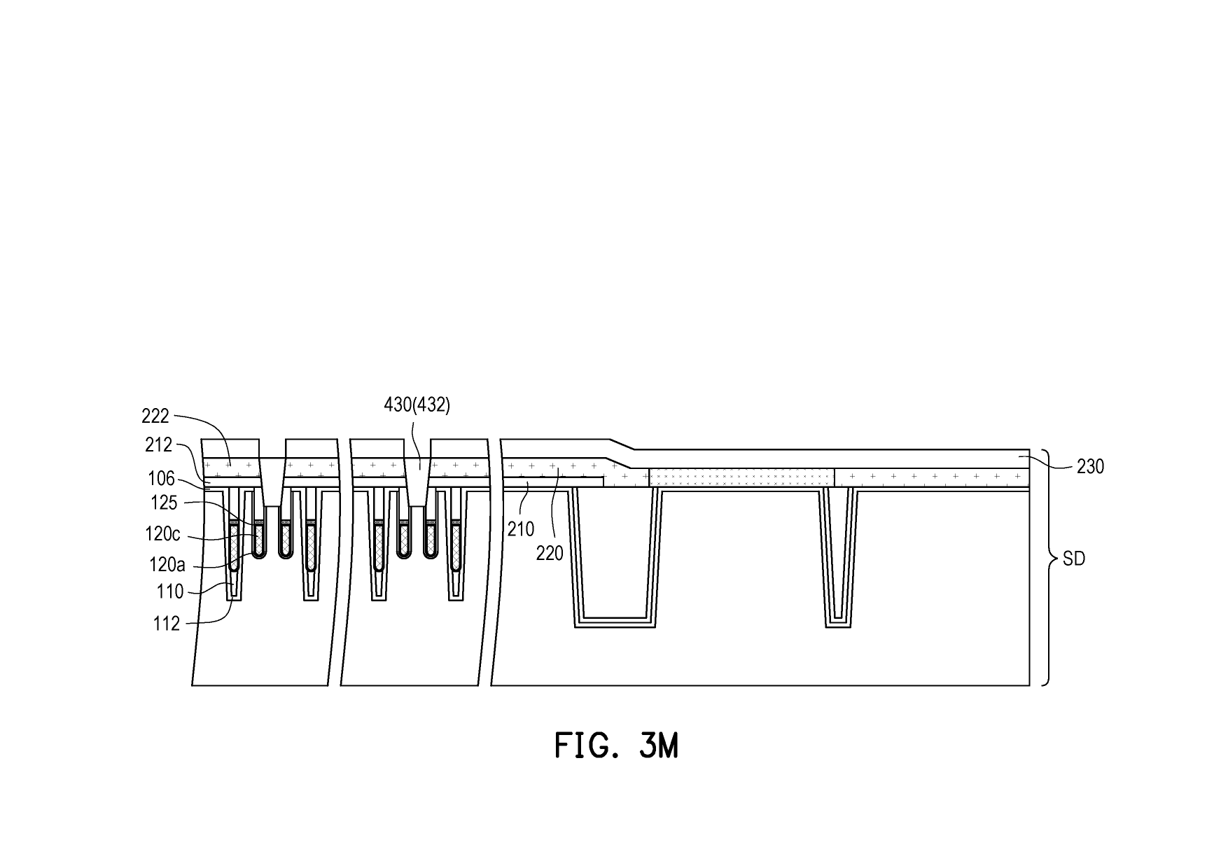

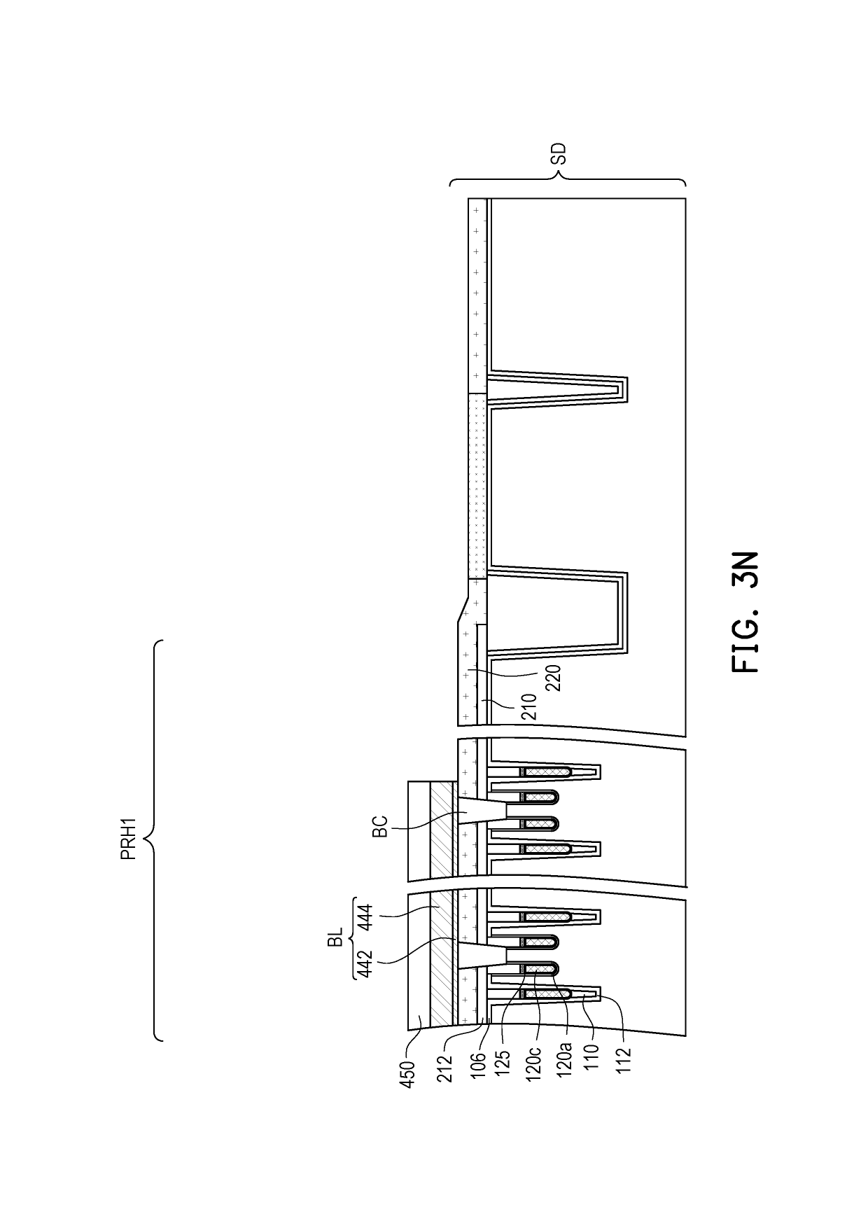

FIG. 2A to FIG. 2L and FIG. 3A to FIG. 3N are cross-sectional schematic diagrams of various stages in the manufacturing method of the semiconductor structure 10A shown in FIG. 1. Referring to FIG. 2A, a semiconductor device SD is provided. The semiconductor device SD includes a substrate 100 and multiple word lines WL embedded in the substrate 100.

The substrate 100 may be an elemental semiconductor substrate, such as a silicon substrate or a germanium substrate; or a compound semiconductor substrate, such as a silicon carbide substrate or a gallium arsenide substrate. In some embodiments, the substrate 100 may be a semiconductor-on-insulator (SOI) substrate. In some embodiments, the top surface of the substrate 100 includes an insulation layer 106.

The substrate 100 includes active regions 102 and isolation regions 104. Isolation structures 110 are filled in the isolation regions 104. In some embodiments, the isolation structures 110 are formed of dielectric materials, for example, silicon oxide (SiO), silicon nitride (SiN), silicon oxynitride (SiON), combinations thereof and/or other suitable materials.

In some embodiments, isolation trenches are formed in the substrate 100 by an etching process, followed by forming liner layers 112 and isolation structures 110 within the isolation trenches.

In some embodiments, after forming the isolation structures 110, a patterning process is performed on the substrate 100 to form word line trenches in the active regions 102 and in the isolation structures 110. Due to different etching rates in the active regions 102 and the isolation structures 110 during the etching process, word line trenches with different depths may be formed in the active regions 102 and the isolation structures 110. In some embodiments, the word line trenches in the isolation structures 110 have a deeper depth than the word line trenches in the active regions 102.

Word lines WL are formed in the word line trenches in the active regions 102 and in the isolation structures 110. The word lines WL include a gate dielectric layer 120a and a conductive layer 120c. The gate dielectric layer 120a is formed on the sidewalls and bottom surfaces of the word line trenches in the active regions 102. Then, the remaining space in the word line trenches is filled with the conductive layer 120c. Optionally, a barrier layer may be formed in the word line trenches in the active regions 102 and in the isolation structures 110 to prevent diffusion of metal ions from the subsequently formed conductive layer 120c. The conductive layer 120c (and the barrier layer) in the active regions 102 and the isolation structures 110 are etched back until a predetermined height is reached.

In some embodiments, the word lines WL also include a work function layer 125. The work function layer 125 may include, for example, doped or undoped polycrystalline silicon, metals (such as tantalum, titanium, tungsten, ruthenium, aluminum, etc.), metal alloys, metal nitrides (such as titanium nitride, titanium silicon nitride, tantalum nitride, tungsten nitride), metal silicides, etc. After depositing the material for forming the work function layer 125, it may be recessed, for example, by an etch-back process, so that the top surface of the work function layer 125 is lower than the top surface of the substrate 100. In some embodiments, a barrier layer may also be included between the conductive layer 120c and the work function layer 125, but the present invention is not limited thereto.

The remaining space in the word line trenches is filled with a cap layer 130. In some embodiments, the cap layer 130 includes nitride such as silicon nitride (SiN), silicon carbon nitride (SiCN), silicon oxycarbide (SiOC), silicon oxycarbonitride (SiOCN), combinations thereof and/or other suitable materials.

The isolation component TI surrounds the array region where the word lines WL are disposed, and is used to separate the array region from the peripheral region. In some embodiments, the isolation component TI includes shallow trench isolation structures or other similar structures.

Subsequently, a dielectric material layer 210 is formed above the substrate 100, and the dielectric material layer 210 extends from above the array region where the word lines WL are arranged to above the isolation component TI on the substrate 100. In some embodiments, the dielectric material layer 210 includes a composite layer of different dielectric materials. For example, the dielectric material layer 210 may include silicon oxide (SiO), silicon nitride (SiN), silicon oxynitride (SiON), combinations thereof and/or other suitable materials.

Next, a semiconductor material layer 220 is formed above the dielectric material layer 210. In some embodiments, the semiconductor material layer 220 is a doped or undoped semiconductor layer. For example, the semiconductor material layer 220 may be doped with p-type dopants or n-type dopants. The dopants of the semiconductor material layer 220 may be selected according to actual application requirements. In some embodiments, the semiconductor material layer 220 includes a polycrystalline silicon layer.

A mask layer 230 is located on the semiconductor material layer 220. In some embodiments, the material of the mask layer 230 may include silicon oxide (for example, silicon oxide formed using tetraethoxysilane (TEOS) as a precursor), silicon nitride, or a combination thereof, or other suitable materials.

A first mask structure 310 is formed above the semiconductor device SD. In this embodiment, the first mask structure 310 is formed on the mask layer 230. In some embodiments, the first mask structure 310 may include, for example, hard mask materials. For instance, the first mask structure 310 may include carbides, such as diamond-like carbon, amorphous carbon film, high selectivity transparency carbon layer, or combinations thereof, or other suitable materials.

A first etching stop layer 320 is formed on the first mask structure 310. The first etching stop layer 320 has a single-layer or multi-layer structure. For example, the first etching stop layer 320 includes a first layer 324 and a second layer 322. In some embodiments, the first etching stop layer 320 includes silicon oxynitride or other suitable materials, wherein the oxygen content in the first layer 324 is higher than that in the second layer 322, while the silicon content in the second layer 322 is higher than the silicon content in the first layer 324.

A second mask structure 330 is formed above the first mask structure 310. In this embodiment, the second mask structure 330 is formed on the first etching stop layer 320. In some embodiments, the second mask structure 330 may include, for example, hard mask materials. For instance, the second mask structure 330 may include carbides, such as diamond-like carbon, amorphous carbon film, high selectivity transparency carbon layer, or combinations thereof, or other suitable materials.

A second etching stop layer 340 is formed on the second mask structure 330. The second etching stop layer 340 has a single-layer or multi-layer structure. For example, the second etching stop layer 340 includes a first layer 344 and a second layer 342. In some embodiments, the second etching stop layer 340 includes silicon oxynitride or other suitable materials, wherein the oxygen content in the first layer 344 is higher than that in the second layer 342, while the silicon content in the second layer 342 is higher than that in the first layer 344.

A first hard mask layer 351 is formed on the second etching stop layer 340. For example, the first hard mask layer 351 may include a spin on carbon (SOC) or a spin on glass (SOG).

A first anti-reflective layer 361 is formed on the first hard mask layer 351. In some embodiments, the first anti-reflective layer 361 may be, for example, a spin on silicon anti-reflection coating (SOSA).

A first photoresist pattern layer PR1 is formed on the first anti-reflective layer 361. For example, a photoresist material is first coated on the first anti-reflective layer 361, followed by exposure and development processes on the aforementioned photoresist material to form the first photoresist pattern layer PR1. The first photoresist pattern layer PR1 includes a first photoresist opening pattern PRH1.

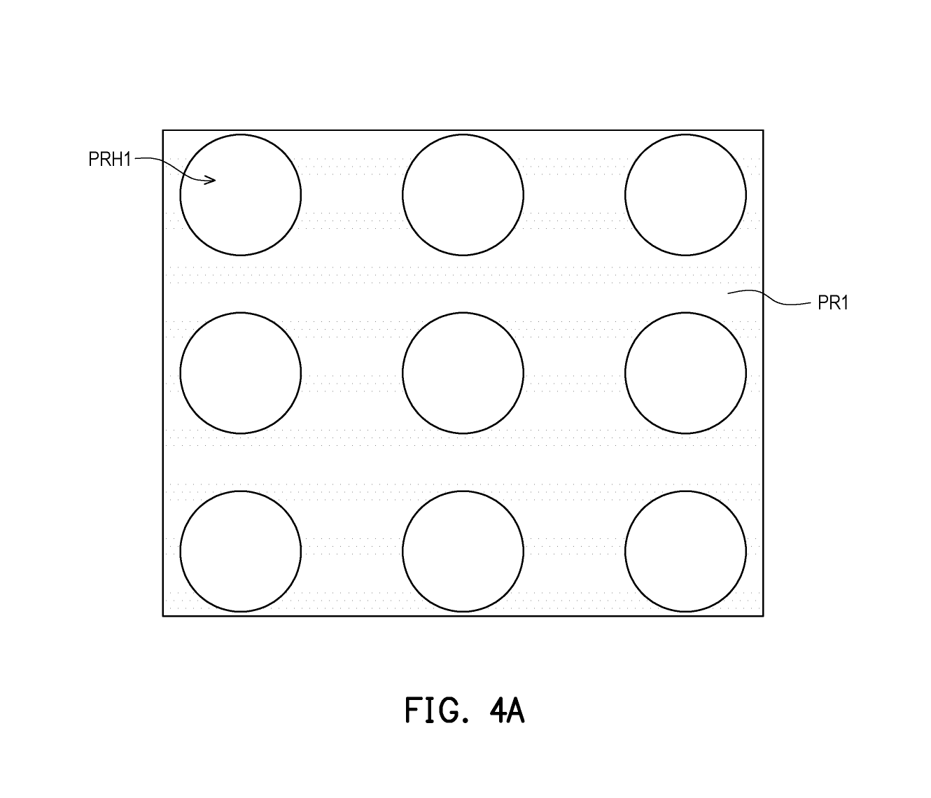

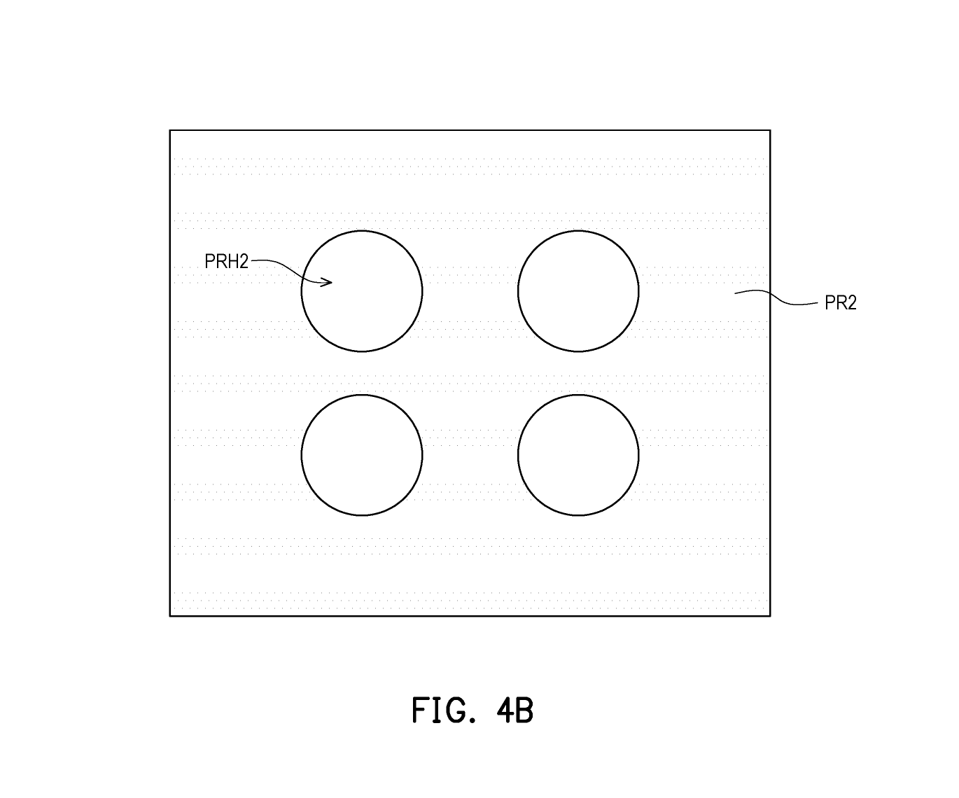

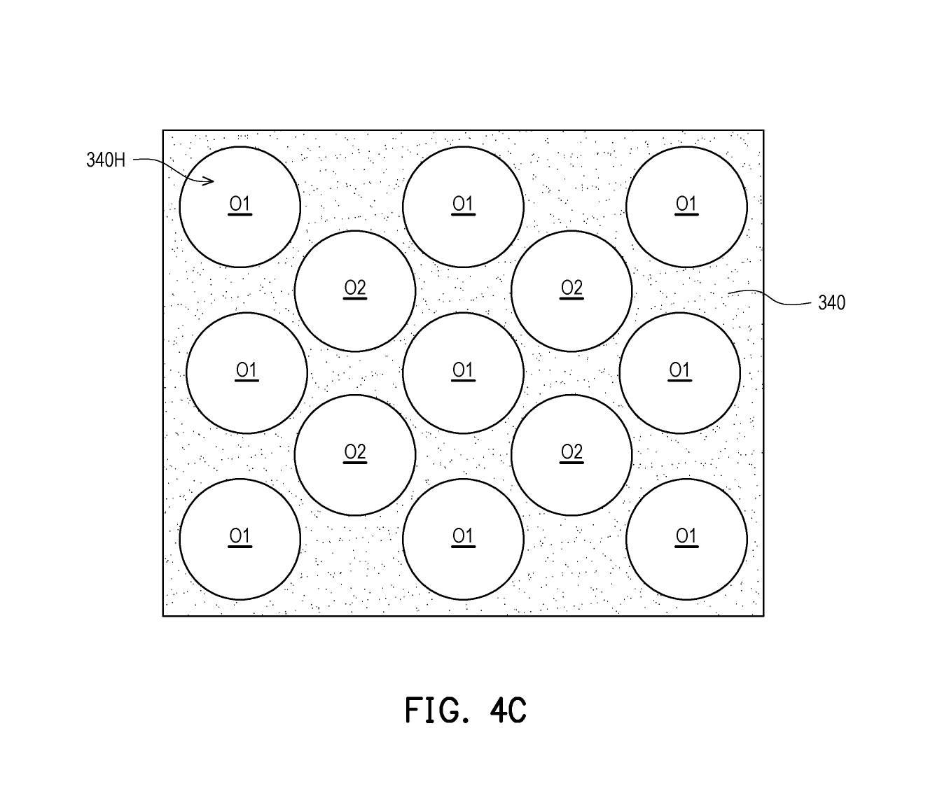

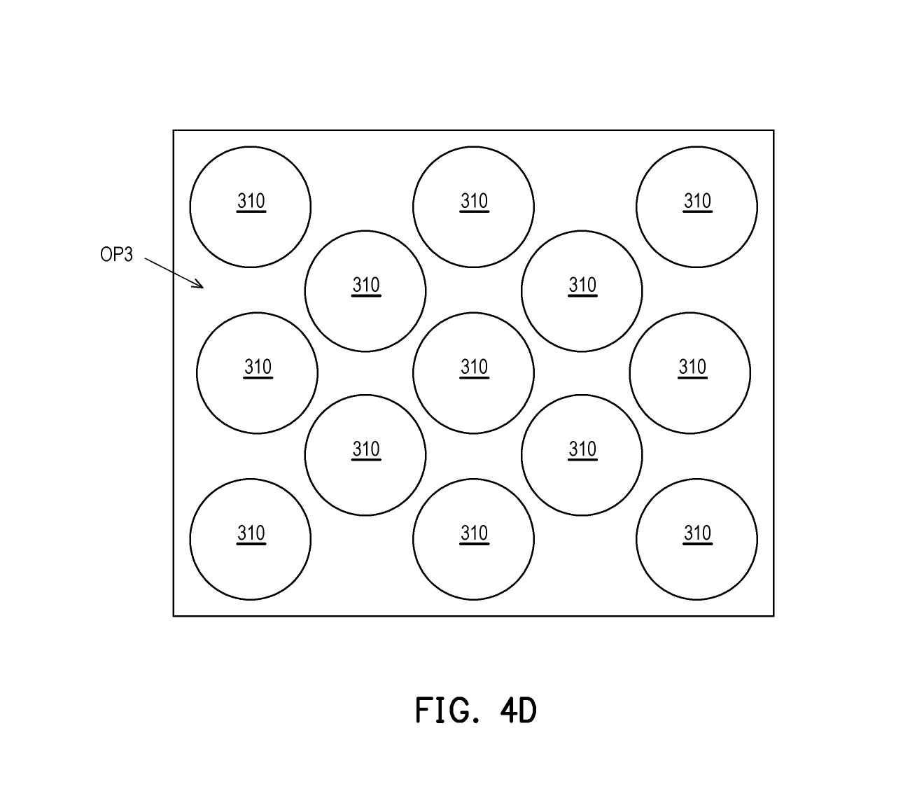

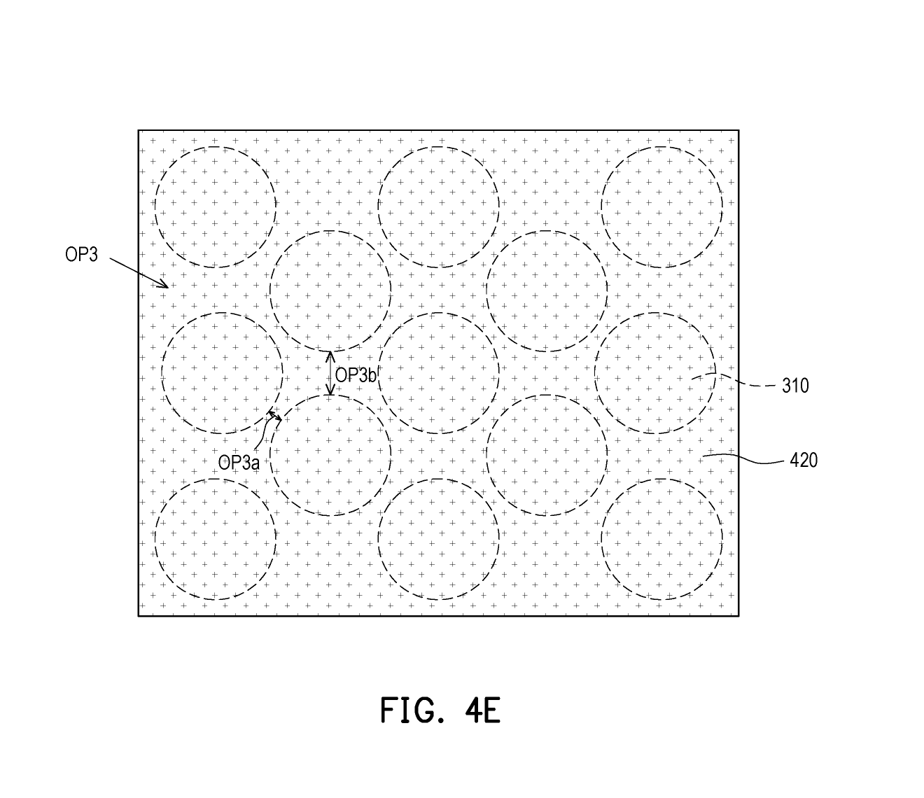

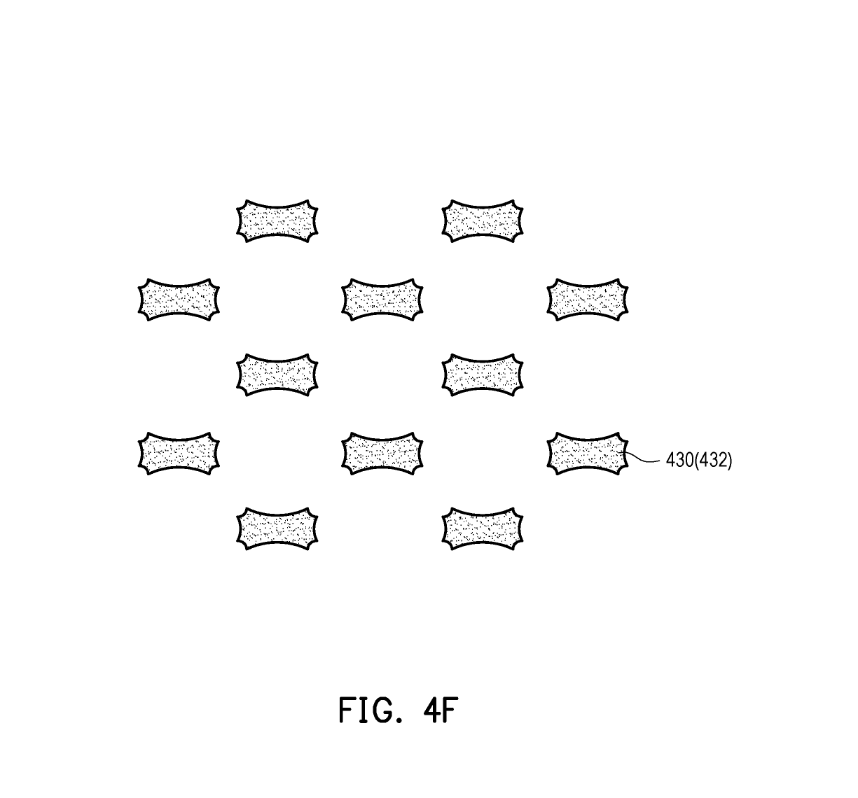

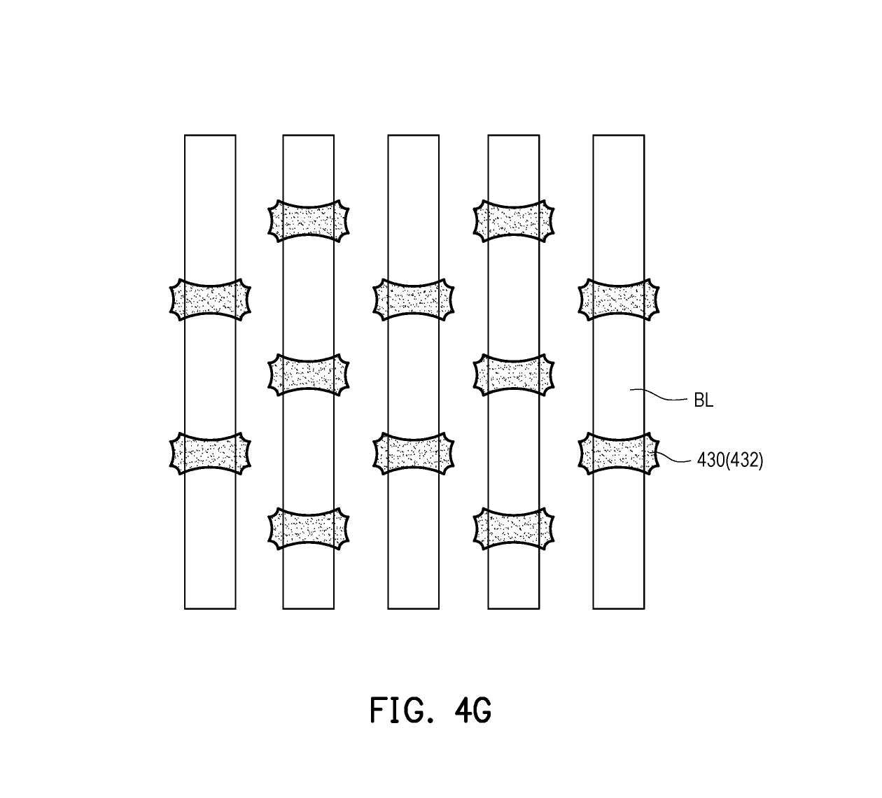

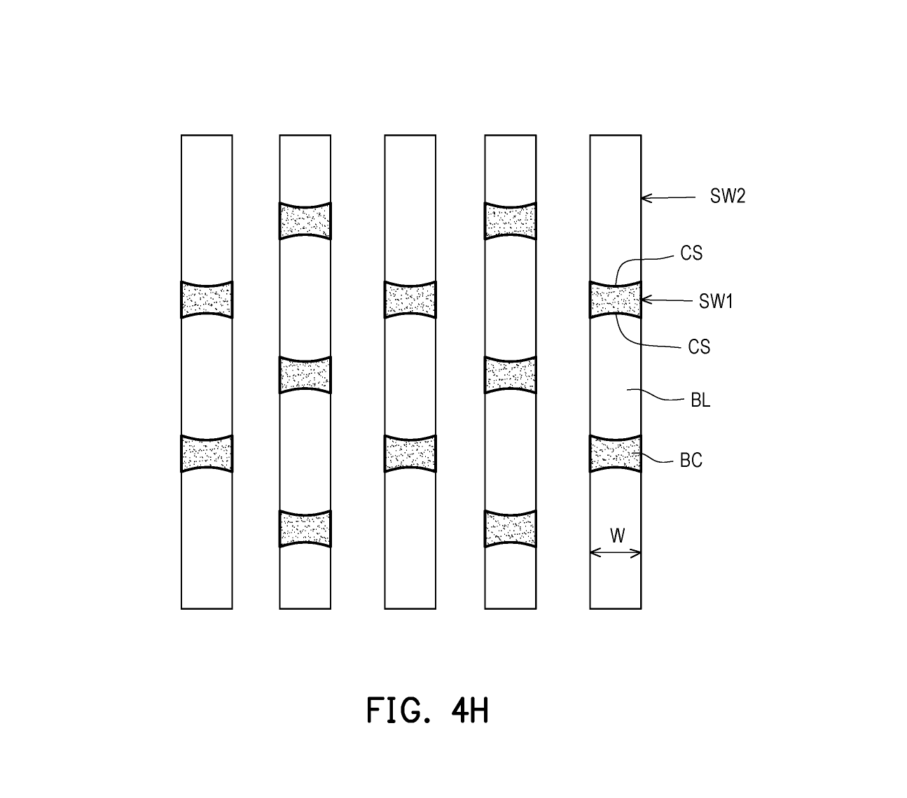

The first photoresist opening pattern PRH1 is transferred to the first anti-reflective layer 361, the first hard mask layer 351, and the second etching stop layer 340. For example, referring to FIG. 2B to FIG. 2E, an etching process is performed using the first photoresist pattern layer PR1 as a mask to form multiple first openings O1 in the second etching stop layer 340. In some embodiments, the first photoresist opening pattern PRH1 may include multiple circular openings, as shown in FIG. 4A. Consequently, the first openings O1 in the second etching stop layer 340 are also circular openings.

The first openings O1 extend through the second layer 342 of the second etching stop layer 340. In some embodiments, over-etching may cause the first openings O1 to extend into the first layer 344, but the present invention is not limited to this.

Then, as shown in FIG. 2F, the remaining first hard mask layer 351 is removed. As shown in FIG. 2G, a second hard mask layer 352 is formed on the second etching stop layer 340 and in the first openings O1. For example, the second hard mask layer 352 may include a spin on carbon (SOC) or a spin on glass (SOG).

A second anti-reflective layer 362 is formed on the second hard mask layer 352. In some embodiments, the second anti-reflective layer 362 may be, for example, a spin on silicon anti-reflection coating (SOSA).

A second photoresist pattern layer PR2 is formed on the second anti-reflective layer 362. For example, a photoresist material is first coated on the second anti-reflective layer 362, followed by exposure and development processes on the aforementioned photoresist material to form the second photoresist pattern layer PR2. The second photoresist pattern layer PR2 includes a second photoresist opening pattern PRH2.

The second photoresist opening pattern PRH2 is transferred to the second anti-reflective layer 362, the second hard mask layer 352, and the second etching stop layer 340. For example, referring to FIG. 2G to FIG. 2K, an etching process is performed using the second photoresist pattern layer PR2 as a mask to form multiple second openings O2 in the second etching stop layer 340. In some embodiments, the second photoresist opening pattern PRH2 may include multiple circular openings, as shown in FIG. 4B. Consequently, the second openings O2 in the second etching stop layer 340 are also circular openings.

The second openings O2 extend through the second layer 342 of the second etching stop layer 340. In some embodiments, over-etching may cause the second openings O2 to extend into the first layer 344, but the present invention is not limited to this.

In this embodiment, the positions of the second openings O2 are interlaced with the positions of the first openings O1. By forming interlaced first openings O1 and second openings O2 in the second etching stop layer 340 through two lithography processes, the spacing between the openings in the second etching stop layer 340 may be reduced. For example, the first openings O1 and the second openings O2 form an opening array 340H, as shown in FIG. 4C.

In this embodiment, the opening array 340H is formed in the second etching stop layer 340 through two lithography processes, but the present invention is not limited to this. In other embodiments, the opening array 340H may be formed through a single lithography process.

Next, as shown in FIG. 2K, the remaining second hard mask layer 352 is removed. As shown in FIG. 2L, an etching process is performed to extend the first openings O1 and the second openings O2 to the top surface of the second mask structure 330. In this embodiment, when extending the first openings O1 and the second openings O2 to the top surface of the second mask structure 330, the second layer 342 in the second etching stop layer 340 is completely removed, leaving only part of the first layer 344 on the top surface of the second mask structure 330.

Referring to FIG. 3A to FIG. 3C, through an etching process, the first openings O1 and the second openings O2 in the first layer 344 are transferred to the second mask structure 330 and the first etching stop layer 320, to form a first opening pattern OP1 in the second mask structure 330 and the first etching stop layer 320. The first opening pattern OP1 may have substantially the same vertical projection pattern as the opening array 340H formed by the first openings O1 and the second openings O2 shown in FIG. 4C.

The first opening pattern OP1 extends through the second layer 322 of the first etching stop layer 320. In some embodiments, over-etching may cause the first opening pattern OP1 to extend into the first layer 324, but the present invention is not limited to this.

Referring to FIG. 3D, a third mask structure 410 is formed on the second mask structure 330 and in the first opening pattern OP1. In some embodiments, the material of the third mask structure 410 includes an oxide, such as silicon oxide or other suitable materials. The third mask structure 410 fills the first opening pattern OP1. In some embodiments, the third mask structure 410 has a high etching selectivity with the material located underneath it, to facilitate the patterning process.

Using the third mask structure 410 as a mask, at least a part of the second mask structure 330 surrounded by the third mask structure 410 is removed. For example, a third photoresist pattern layer PR3 is first formed over the third mask structure 410, where the third photoresist pattern layer PR3 is located above the peripheral region of the substrate 100. Then, using the third photoresist pattern layer PR3 as a mask, a portion of the third mask structure 410 is removed until a first part of the second mask structure 330 is exposed, as shown in FIG. 3E. Then, referring to FIG. 3F, using the third mask structure 410 as a mask, the first part of the second mask structure 330 is etched to form a second opening pattern OP2 in the third mask structure 410. The second opening pattern OP2 may have a shape substantially complementary to the shape of the vertical projection of the opening array 340H shown in FIG. 4C on the semiconductor device SD.

In some embodiments, part of the first etching stop layer 320 (for example, part of the second layer 322) may be located in the second opening pattern OP2.

In some embodiments, the third photoresist pattern layer PR3 and the second mask structure 330 may be removed simultaneously.

Referring to FIG. 3G, through the second opening pattern OP2, an etching process is performed on the part of the first etching stop layer 320 (part of the second layer 322) located in the second opening pattern OP2, until the first layer 324 of the first etching stop layer 320 is exposed. Referring to FIG. 3H, the etching process is continued through the second opening pattern OP2 to etch the first etching stop layer 320 and the first mask structure 310 located under the third mask structure 410, to form a third opening pattern OP3 in the first etching stop layer 320 and the first mask structure 310.

In some embodiments, while forming the third opening pattern OP3, the remaining part (i.e., the second part) of the second mask structure 330 may be removed.

In some embodiments, the shape of the vertical projection of the second opening pattern OP2 on the semiconductor device SD may be substantially the same as the shape of the vertical projection of the third opening pattern OP3 on the semiconductor device SD; while at least a part of the shape of the vertical projection of the second opening pattern OP2 (or the third opening pattern OP3) on the semiconductor device SD may be substantially complementary to at least a part of the shape of the vertical projection of the first opening pattern OP1 (refer to FIG. 3A to FIG. 3C) on the semiconductor device SD.

Referring to FIG. 3I, optionally, a filling layer 420 may be filled into the third opening pattern OP3. Referring to both FIG. 3I and FIG. 4E, the third opening pattern OP3 includes a region OP3a with small gaps and a region OP3b with large gaps. The deposition rate of the filling layer 420 is faster in the region OP3a with small gaps, therefore, the filling layer 420 completely covers the region OP3a with small gaps, and the filling layer 420 does not completely cover the region OP3b with large gaps. In some embodiments, the filling layer 420 may include polymeric material containing carbon chains formed by reaction gases including CH₄．and CH₄+. Specifically, alkane materials may be deposited first, with alkane materials including but not limited to CH₄. Under the influence of an electric field or magnetic field, CH₄ may form reaction gases CH₄．and CH₄+, which in turn form the filling layer 420 with long carbon chains. In some embodiments, the filling layer 420 may contain polymeric materials with different carbon chain lengths. In FIG. 3I and FIG. 4E, the filling layer 420 is shown as a blanket-like shape covering the entire surface, but in reality, the filling layer 420 has many holes in the region OP3b with large gaps, causing the filling layer 420 to not completely cover the region OP3b with large gaps.

Referring to FIG. 3J and FIG. 3K, the semiconductor device SD may be etched through the third opening pattern OP3 to form a fourth opening pattern OP4 in the semiconductor device SD. The fourth opening pattern OP4 extends through the mask layer 230, the semiconductor material layer 220, and the dielectric material layer 210, and extends into the substrate 100. In this embodiment, part of the cap layer 130 may also be removed during the aforementioned process.

Referring to FIG. 4E, in this embodiment, before etching the semiconductor device SD, the filling layer 420 may be filled into the region OP3a with small gaps. Therefore, when etching the semiconductor device SD, at the area corresponding to the region OP3a with small gaps, the etchant may be blocked by the filling layer 420. On the other hand, since the region OP3b with large gaps is not completely covered by the filling layer 420, when etching the semiconductor device SD, at the area corresponding to the region OP3b with large gaps, the etchant may easily etch through the filling layer 420 and etch the semiconductor device SD located underneath. Based on this, although the third opening pattern OP3 is substantially a mesh-like opening, a fourth opening pattern OP4 containing multiple individually separated contact openings CV may be formed in the semiconductor device SD.

In this embodiment, the filling layer 420 may be utilized to make the vertical projection shape of the fourth opening pattern OP4 different from the vertical projection shape of the third opening pattern OP3, but the present invention is not limited to this. In other embodiments, the step of depositing the filling layer 420 may be omitted, so that the vertical projection shape of the fourth opening pattern OP4 is substantially equal to that of the third opening pattern OP3.

In addition, in this embodiment, the first mask structure 310 may include multiple individually separated circular island structures (refer to FIG. 4D), and the third opening pattern OP3 is substantially a mesh-like opening, but the present invention is not limited to this. In other embodiments, the circular island structures of the first mask structure 310 may contact each other, making the third opening pattern OP3 substantially include multiple individually separated openings.

In some embodiments, after utilizing an etching process to form the fourth opening pattern OP4 in the semiconductor device SD, the semiconductor material layer 220 may include multiple first island structures 222 separated from each other, and the dielectric material layer 210 may include multiple second island structures 212 separated from each other. The vertical projection shapes of the first island structures 222 and the second island structures 212 are substantially the same (as shown by the circular island structures in the first mask structure 310 in FIG. 4D).

Referring to FIG. 3L, a filling material layer 430 may be formed on the mask layer 230 and in the fourth opening pattern OP4. In some embodiments, the filling material layer 430 may include doped polycrystalline silicon, metal, or metal nitride. In an embodiment, the filling material layer 430 may be formed through a deposition process such as physical vapor deposition, chemical vapor deposition, atomic layer deposition, or other suitable methods.

Compared to circular openings, the filling material layer 430 may be more easily filled into the contact opening CV. For example, when depositing the filling material layer 430 into circular openings, closed voids may be formed due to the deposition rate on the sidewalls being too fast. In this embodiment, depositing the filling material layer 430 in non-circular (e. g., star-shaped) openings CV may reduce the probability of the formation of the closed voids.

Referring to FIG. 3M, optionally, an etch-back process may be performed on the filling material layer 430 to remove the part of the filling material layer 430 that extends beyond the mask layer 230. In some embodiments, after performing the etch-back process, the height of the top surface of the filling material layer 430 may be lower than the height of the top surface of the mask layer 230.

In other embodiments, the part of the filling material layer 430 that extends beyond the mask layer 230 may be removed through a planarization process. In some embodiments, at least part of the mask layer 230 may also be removed during the aforementioned planarization process, making the top surface of the filling material layer 430 substantially aligned with the top surface of the mask layer 230 after the planarization process. In some embodiments, after performing the etch-back process, the filling material layer 430 may include multiple individually separated structures 432, as shown in FIG. 4F. Referring to FIG. 3N, the mask layer 230 may be removed. For example, the mask layer 230 may be removed by an etching process or a planarization process. Then, multiple bit lines BL may be formed on the filling material layer 430.

In some embodiments, the bit lines BL may include a multi-layer structure, for example, including a conductive layer 442 and a conductive layer 444. The conductive layer 442 and the conductive layer 444 may include doped polycrystalline silicon, metal, or metal nitride, such as tungsten, titanium, titanium nitride, or other suitable materials. The conductive layer 442 may include titanium nitride, and the conductive layer 444 may include tungsten.

In some embodiments, a conductive material layer may be comformally formed. Then, a hard mask layer 450 may be formed on the conductive material layer. The conductive material layer may be etched using the hard mask layer 450 as a mask to form the bit lines BL. The filling material layer 430 may be etched using the bit lines BL and the hard mask layer 450 as a mask to form multiple contact structures BC, as shown in FIG. 4G and FIG. 4H. In some embodiments, the semiconductor material layer 220 under the bit lines BL may also be etched.

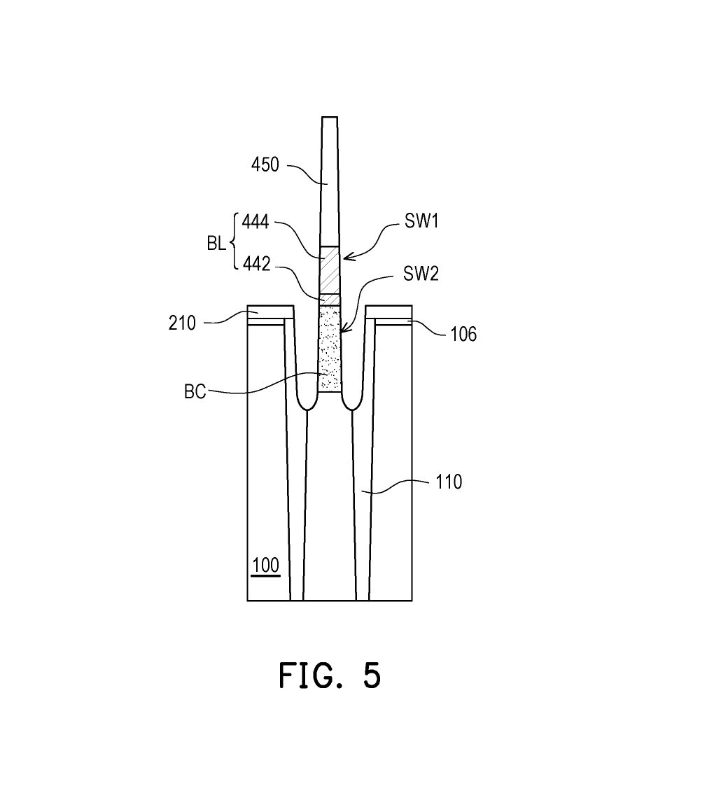

In some embodiments, the vertical projection of at least one of the contact structures BC on the semiconductor device may include a shape with concave sides CS, and the bit lines BL may overlap with the concave sides CS. Each contact structure BC may include multiple concave sides CS. The sidewall SW1 of the contact structure BC may be aligned with the sidewall SW2 of the bit line BL, as shown in FIG. 4H and FIG. 5. In some embodiments, the contact structure BC may have a cross-sectional shape that is narrower at the top and wider at the bottom. Specifically, the width of the contact structure BC on the side closer to the bit line BL may be smaller than the width of the contact structure BC on the side closer to the substrate 100.

In summary, the semiconductor structure of the present invention may include contact structures with small feature dimensions, which is therefore beneficial for improving the performance and integration level of the device.

What is claimed is:

1. A manufacturing method of a semiconductor structure, comprising:
forming a first mask structure above a semiconductor device;
forming a second mask structure above the first mask structure;
forming a first opening pattern in the second mask structure;
forming a third mask structure above the second mask structure and in the first opening pattern;
removing at least part of the second mask structure surrounded by the third mask structure using the third mask structure as a mask, to form a second opening pattern in the third mask structure;
etching the first mask structure located below the third mask structure through the second opening pattern, to form a third opening pattern in the first mask structure;
etching the semiconductor device through the third opening pattern, to form a fourth opening pattern in the semiconductor device;
forming a filling material layer in the fourth opening pattern;
forming a plurality of signal lines above the filling material layer; and
etching the filling material layer using the plurality of signal lines as a mask, to form a plurality of contact structures.

2. The manufacturing method of claim 1, wherein removing the at least part of the second mask structure surrounded by the third mask structure using the third mask structure as the mask comprises:
forming a photoresist pattern layer above the third mask structure;
removing a part of the third mask structure using the photoresist pattern layer as a mask, until a first part of the second mask structure is exposed; and
etching the first part of the second mask structure using the third mask structure as the mask, to form the second opening pattern.

3. The manufacturing method of claim 2, wherein a second part of the second mask structure is removed simultaneously with forming the third opening pattern.

4. The manufacturing method of claim 1, further comprising, before etching the semiconductor device through the third opening pattern:
filling a filling layer in the third opening pattern, wherein the third opening pattern includes a region with small gaps and a region with large gaps, wherein the filling layer completely covers the region with small gaps, and the filling layer does not completely cover the region with large gaps.

5. The manufacturing method of claim 4, wherein the filling layer comprises a polymer material.

6. The manufacturing method of claim 1, wherein at least a part of a shape of a vertical projection of the second opening pattern on the semiconductor device is substantially complementary in shape to at least a part of a shape of a vertical projection of the first opening pattern on the semiconductor device.

7. The manufacturing method of claim 1, wherein a shape of a vertical projection of at least one of the plurality of contact structures on the semiconductor device comprises a concave side, and at least one of the plurality of signal lines overlaps with the concave side.

8. A semiconductor structure, comprising:
a semiconductor device;
a plurality of contact structures, located in the semiconductor device, wherein a shape of a vertical projection of at least one of the plurality of contact structures on the semiconductor device comprises a concave side; and
a plurality of first signal lines, located on the plurality of contact structures, and at least one of the plurality of first signal lines overlaps with the concave side.

9. The semiconductor structure of claim 8, wherein the semiconductor device comprises:
a substrate; and
a plurality of second signal lines, embedded in the substrate, wherein the plurality of first signal lines comprise bit lines, and the plurality of second signal lines comprise word lines.

10. The semiconductor structure of claim 8, wherein a sidewall of the at least one of the plurality of contact structures is aligned with a sidewall of the at least one of the plurality of first signal lines.
